(19) United States
(12) Patent Application Publication
(10) Pub. No.: US 2022/0360211 A1
(43) Pub. Date: Nov. 10, 2022

(54) CORRUGATED SOLAR SYSTEMS AND METHODS

(71) Applicant: Other Lab, LLC, San Francisco, CA (US)

(72) Inventors: Saul Thomas Griffith, San Francisco, CA (US); Samuel Eli Calisch, Berkeley, CA (US); Joshua Land, San Francisco, CA (US); Brenton Piercy, San Francisco, CA (US); Peter Sturt Lynn, San Francisco, CA (US); Pushan Panda, San Francisco, CA (US); Albert Que, San Francisco, CA (US)

(21) Appl. No.: 17/736,650

(22) Filed: May 4, 2022

Related U.S. Application Data
(60) Provisional application No. 63/183,891, filed on May 4, 2021.

(51) Int. Cl. H02S 30/10; H02S 20/23

(52) U.S. Cl. CPC H02S 30/10; H02S 20/23

(57) ABSTRACT

A system with one or more solar modules comprising a plurality of solar cells, each of the solar modules having a plurality of corrugations defined by a plurality of alternating elongated top channels and elongated bottom channels that extend between opposing ends along first parallel axes, the elongated bottom channels defined by first pairs of sidewalls extending from respective caps, and the elongated top channels defined by second sidewalls extending from respective bases.

### CROSS-REFERENCE TO RELATED APPLICATIONS

This application is a non-provisional of and claims the benefit of U.S. Provisional Application No. 63/183,891, filed May 4, 2021, entitled “STRUCTURALLY OPTIMIZED CORRUGATED SOLAR,” with attorney docket number 0105198-035PR0. This application is hereby incorporated herein by reference in its entirety and for all purposes.

### BACKGROUND

Solar is anticipated to supply a substantial portion of future energy supply, some estimates are 50% or more, yet to date it contributes only about 1% of total energy or 2% of electricity generation. Residential and commercial rooftop solar potential is estimated at 1,100 GW of capacity and 1,400 TWh of annual generation, but penetration in the US is still only a few percent of buildings. These studies use conservative assumptions of rooftop coverage area and are constrained to existing designs—cheaper solar enables larger installations and larger installations enable cheaper solar, so rooftop potential is arguably much higher. Cost, siting, and aesthetic constraints limit market penetration, particularly in the residential setting. By integrating more tightly into buildings, solar photovoltaics can be used on previously underutilized roofs and in larger per roof installations. Costs of solar energy have fallen greatly, so far in fact that it is soft costs, not component or cell costs, that dominate the installed price, whether installed residentially or at utility scale. Module costs are now typically about 30¢/W, installed costs industrially hover around $1/W, and installed cost on rooftops in the US average around $3/W. Australia has already achieved BOS cost reductions and installs solar at about $1/W which finances out to an LCOE of 5-6c/kWh, less than half of the cost of the average US residential retail of 13c/kWh.

Solar energy is underutilized and in need of further deployment both nationally and globally. Australia, with rooftop solar LCOE now comfortably below grid electricity rates, already has 20% penetration on residential rooftops and analysts see no end to the uptake. United States rooftops alone have the potential to generate 40% of the retail electricity sold in 2019, though the total amount of solar energy produced in the US in 2019 amounted to 2% of the total energy used. These studies use conservative assumptions of rooftop coverage area and are constrained to existing designs—cheaper solar enables larger installations and larger installations enable cheaper solar, so rooftop potential is arguably much higher. Expanding photovoltaic installations could drastically reduce residential energy costs to the consumer and demand on the grid. Creating a diversified power portfolio in the home made up of grid, solar, and storage can prevent and mitigate against rolling black outs and grid overload at peak use times. If installation costs can be paired with another home system, it would create larger gains in the costs-to-savings ratio for homeowners new to solar power generation. To bring solar into the hands of consumers and thereby into the larger electrical network, residential solar needs to become further simplified.

Over the last four years there has been a drop, followed by general plateau in residential solar installations when compared with the decade prior. Even with this decrease, US residents are accepting solar power as their concern for climate change grows and the price of solar continues to drop. This begs the question, “why are we not installing more residential photovoltaics?” The answer is multi-tiered, a solar soup comprising soft installation costs, home structural stability, solar-to-home electrical integration, overall system aesthetics, the business model of the US construction business, and even workforce training and certification. A fully integrated system that can be easily installed and has significant overlap with other home construction costs could introduce a simple solution to getting solar power into the hands of the homeowner.

Backyard space and surrounding acreage is plentiful in many homes around the country, though more often than not that space has a primary use (e.g., gardens, playgrounds, landscaping) that would be overtaken if a solar array was to be installed. Similarly, low-income housing and many homes in urban areas are tightly packed, leaving no room for surrounding property and associated large format solar arrays. This leaves the roofs of our buildings open to employ for solar energy generation. Tools like Google's Project Sunroof can help the homeowner determine the viability of a solar installation on their home along with estimated cost savings, already reducing the workflow for parties interested in bringing solar to their rooftops. As more homeowners realize the potential of at-home solar (and as storage costs continue to drop) and the evaluation process is simplified, the market will grow and factors such as the installation process and architectural aesthetics become the bottleneck for solar integration.

### BRIEF DESCRIPTION OF THE DRAWINGS

FIG. 1 illustrates an example of a solar system disposed on a roof of a house that comprises a plurality of corrugated solar modules.

FIG. 2 illustrates a close-up perspective view of a solar system disposed on a roof of a house that comprises a plurality of corrugated solar modules.

FIG. 3 illustrates one example embodiment of a corrugated solar module that comprises a plurality of solar cells.

FIG. 4 illustrates another example embodiment of a corrugated solar module that comprises a plurality of solar cells.

FIG. 5 illustrates an example embodiment of a terraced solar module that comprises a plurality of solar cells disposed in a terraced configuration, where one or more solar cells are disposed on respective terrace plates, with the terrace plates being terraced from each other via first and second primary sidewalls and an offset sidewall.

FIG. 6 illustrates a close-up view of a portion of the terraced solar module of FIG. 5.

FIG. 7 illustrates an example of a solar module comprising a plurality of layers including a top layer, a solar cell net or photovoltaic net, a wiring system, an encapsulant layer and a substructure.

FIG. 8 illustrates an example of a solar system comprising a plurality of solar modules disposed on the roof of a building over or along with a corrugated roofing material with flashing being disposed on the roof of the building as well.

FIG. 9 illustrates an example of an embodiment of a corrugated solar module being disposed on and corresponding with a corrugated roofing material.

FIG. 10 illustrates an example embodiment of a solar system comprising a plurality of terraced solar modules disposed on roofing material, with a portion of some peripheral edges of solar modules and/or roofing material being configured to overlap and couple together.

FIG. 11 illustrates an example of a solar system comprising one or more corrugated solar modules having support bars extending through opposing edges of the one or more corrugated solar modules and perpendicular to and axis of rows of solar cells.

FIG. 12 illustrates a first side perspective view of a plurality of solar systems grouped together in an array.

FIG. 13 illustrates a second side perspective view of a plurality of solar systems grouped together in an array.

FIG. 14 illustrates another embodiments of a solar system that comprises one or more corrugated solar modules held by a plurality of cables, with the one or more corrugated solar modules assuming a curved configuration.

FIG. 15 illustrates an example of a solar module comprising a plurality of fastener strips disposed along caps of the solar module with fasteners installed or being installed at the fastener strips.

FIG. 16 illustrates an example of a solar module comprising a fastener strip that includes a label that can include a measuring guide, branding, installation instructions, a warning label and the like.

FIG. 17 illustrates an example of a solar module mounted such that corrugations and solar cells are disposed parallel to the path of the sun.

FIG. 18 illustrates an example embodiment of a solar module having rows of solar cells disposed on only one side of corrugations with the solar modules oriented relative to the angle of the path of the sun.

FIG. 19a illustrates an example embodiment where a seal is disposed at an end of a solar module between a top layer and a substrate layer to provide a seal protecting internal elements of the solar module.

FIG. 19b illustrates an example of a U-seal disposed surrounding an end of a solar module, including surrounding an end of the top layer, the substrate layer and the internal elements to provide a seal protecting internal elements of the solar module.

FIG. 19c illustrates an example embodiment comprising a rolled edge at an end of a solar module defined by rolled ends of the top layer and the substrate layer that provide a seal protecting internal elements of the solar module.

FIGS. 20a and 20b illustrate an example of a solar module comprising a planar photovoltaic panel disposed on a corrugated substrate.

FIG. 21 illustrates an example embodiment where a pair of solar modules are coupled at an overlapping area with a seal between the modules.

FIG. 22 illustrates an example of a solar system comprising a plurality of solar modules coupled to a building, including the roof and a wall of the building.

FIGS. 23a, 23b and 23c illustrate an example of a support line coupling with a plurality of slots in a solar module such that the solar module can be held or suspended by the support line.

FIG. 24 illustrates an example of a solar system comprising a plurality of solar modules suspended over a canal.

FIG. 25 illustrates a method of manufacturing a solar module.

FIG. 26 illustrates corrugated mass scaling, areal density of panel vs. flexural rigidity comparing flat glass to corrugated glass, demonstrating 20× density reduction for the same bending stiffness as a standard PV panel.

FIG. 27 illustrates corrugated mass scaling, areal density of panel vs. flexural rigidity comparing flat glass to corrugated polycarbonate, showing 10× density reduction with simplified manufacturing.

FIGS. 28a, 28b, 29a and 29b illustrate simulating yearly generation and hourly power profiles for flat and corrugated panels subject to local irradiance and roof pitch, corrugation can increase yearly generation by more than 5%, particularly during off peak hours when demand is highest.

It should be noted that the figures are not drawn to scale and that elements of similar structures or functions are generally represented by like reference numerals for illustrative purposes throughout the figures. It also should be noted that the figures are only intended to facilitate the description of the preferred embodiments. The figures do not illustrate every aspect of the described embodiments and do not limit the scope of the present disclosure.

### DETAILED DESCRIPTION

Various embodiments include using corrugated structures to build a structurally optimized solar photovoltaic product with a lower possible weight and cost per watt installed. For example, in some embodiments, equivalent stiffness to non-corrugated form factors can be achieved using 10 times less structural materials than a conventional panel, and simultaneously, solar production can be increased by 5-10% over the year, principally during the important off-peak hours when demand typically outstrips supply. Further, on non-ideal roof orientations and partial shading conditions, the improvements can be especially high in some example. In various embodiments, corrugated solar panels can have module costs 20% lower than conventional solar panels with substantial further savings in BOS, particularly installation. Corrugated solar panels of various embodiments can be made compliant with existing design constraints, including wind, snow, and impact loads, as well as electrical and fire regulations and standard roofing installation practices. Some examples can constrain the corrugations to those easily fabricated with existing PV production lines and a corrugated structural metal, composite, or plastic integrated with an automated layup and laminating processes. Simulations can be used to model and optimize lighter weight, higher production, lower cost corrugated sheets to dramatically expand the penetration of residential photovoltaics, and the like.

Various embodiments can provide benefits to the residential solar market, including: 1) Cost savings in new solar home construction 2) System wide cost reduction for solar retrofits at existing roof end-of-life, 3) Accelerated residential clean energy adoption, 4) Reduction in solar installation costs, helping to reverse current debilitating trends for installers in the market, 5) Approachable solar aesthetics and differentiated product in a growing roofing market, and 6) Reduction in complexity, minimization of componentry, including the elimination of racking and framing. Various examples can reduce system-wide soft costs and the balance of system costs, along with lowering the total mass and cost of the installation.

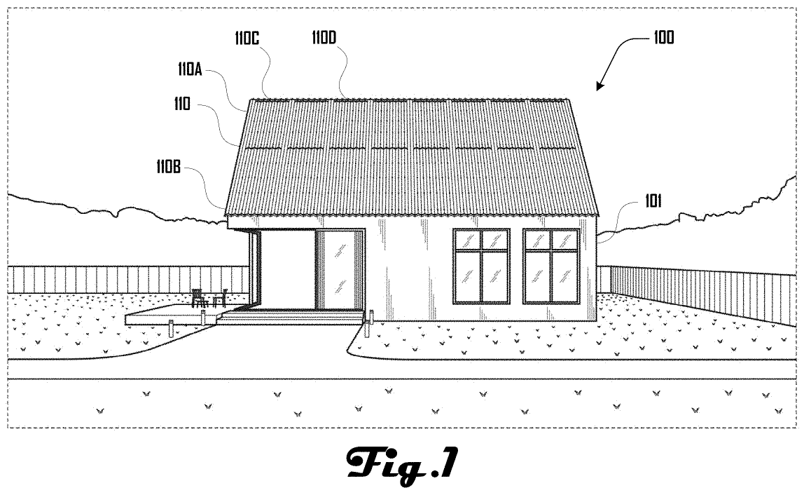

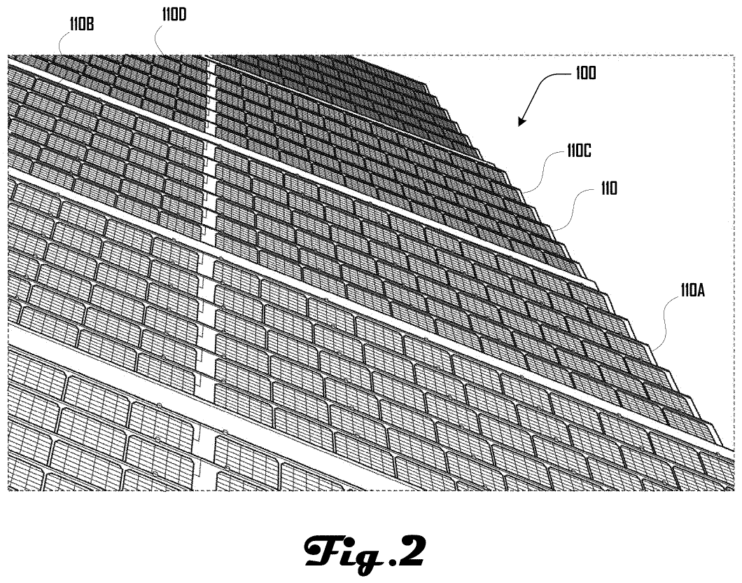

The example FIG. 1 shows how home aesthetics can be preserved with a solar integrated roofing system in some embodiments. Specifically, FIG. 1 illustrates an example of a solar system 100 disposed on a roof of a house 101, which comprises a plurality of corrugated solar modules 110 (e.g., 110A, 110B, 110C, 110D). FIG. 2 illustrates a close-up perspective view of a solar system 100 disposed on a roof of a house, which comprises a plurality of corrugated solar modules 110 (e.g., 110A, 110B, 110C, 110D).

In various embodiments, weight-to-compressive-strength ratio can be optimized and corrugations can be designed to withstand relevant conditions and requirements (for instance, those outlined in the appropriate chapters (namely 3, 4, 8 and 9) of the 2015 International Residential Code (codes.iccsafe.org/content/IRC2015P3) and ASCE 7: Minimum Design Loads for Buildings and Other Structures (ascelibrary.org/doi/book/10.1061/asce7)). Creating sinusoidal corrugations in the paneling can, in some embodiments, provide system wide solutions and cost savings by way of its design. Corrugations in various examples can provide the compressive strength mentioned above, compared to that of flat roofing stock.

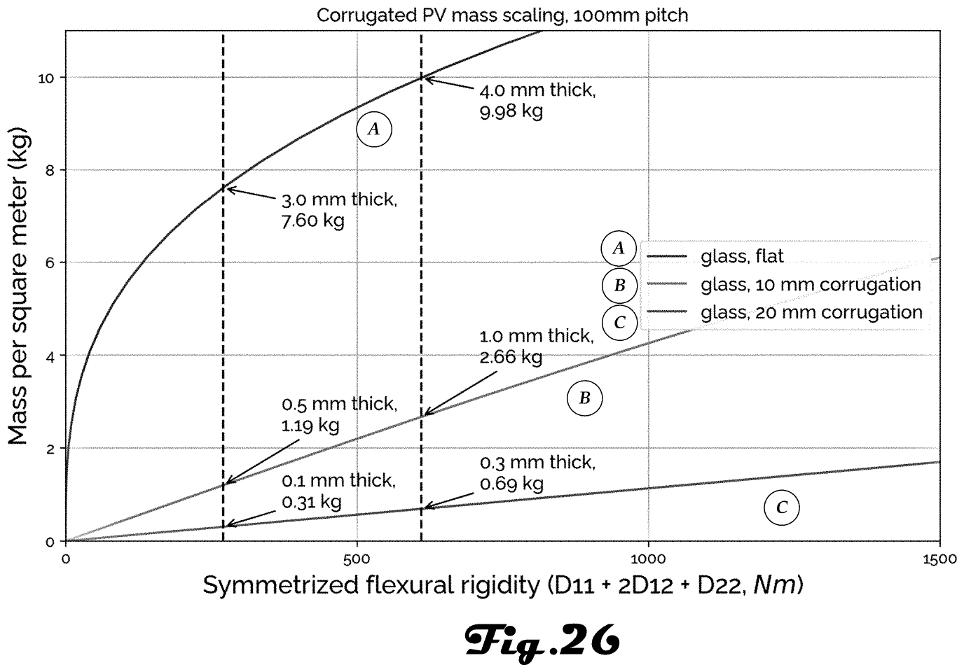

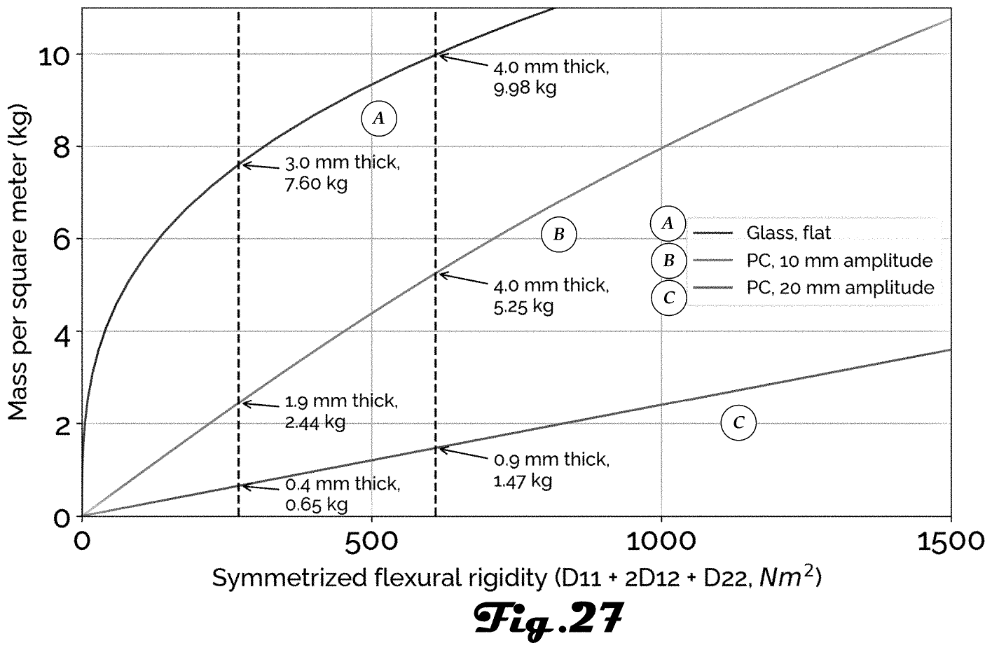

In FIGS. 26 and 27, an equivalent plate model is used to show how corrugations of some embodiments can dramatically decrease required weight of structural materials. Specifically, FIG. 26 and FIG. 27 illustrate corrugated mass scaling, areal density of panel vs. flexural rigidity with FIG. 26 comparing flat glass to corrugated glass, demonstrating 20× density reduction for the same bending stiffness as a standard PV panel and FIG. 27 comparing flat glass to corrugated polycarbonate, showing 10× density reduction with simplified manufacturing.

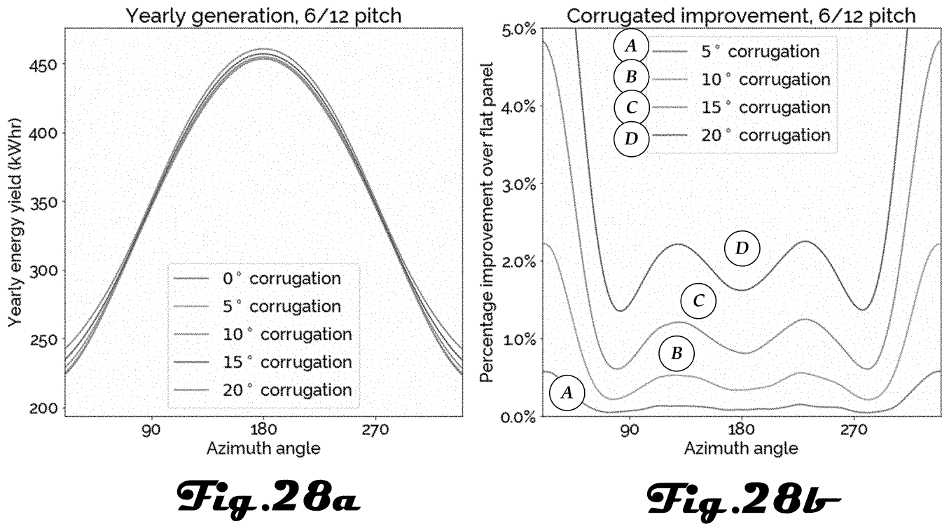

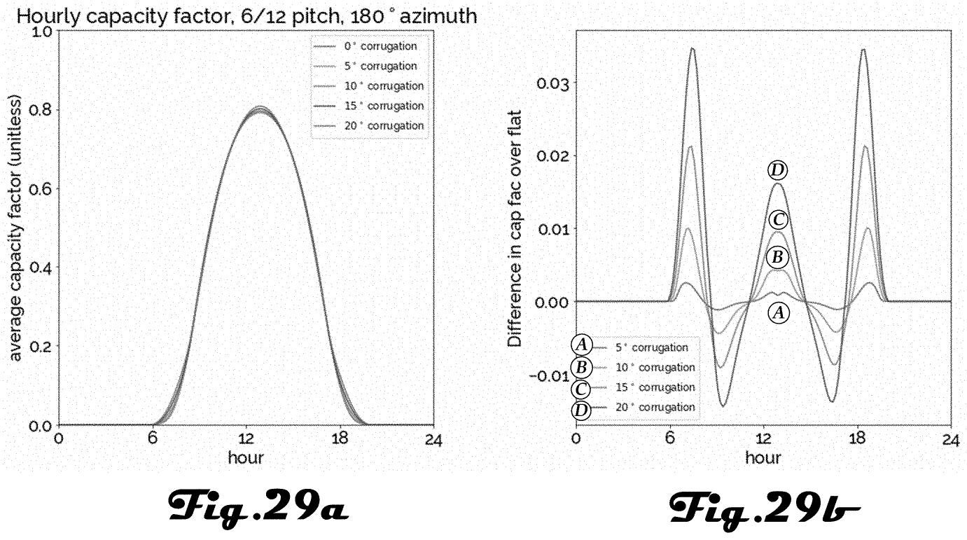

In FIGS. 28a, 28b, 29a and 29b, PVlib (William F. Holmgren, Clifford W. Hansen, and Mark A. Mikofski. “pvlib python: a python package for modeling solar energy systems.” Journal of Open Source Software, 3(29), 884, (2018). doi.org/10.21105/joss.00884) is used to simulate the increase in yearly generation and the hourly power profiles of the corrugated and flat solar product of various examples. As shown in FIGS. 28a, 28b, 29a and 29b, subject to local irradiance and roof pitch, corrugation of various embodiments can increase yearly generation by more than 5%, particularly during off peak hours when demand is highest.

The structural advantages of corrugation can likewise apply to industrial solar where, because of scale, the total system mass and complexity are proxy for cost. Module costs are getting low enough that the LCOE benefit of tracking could be negated by a static technology that gains this benefit through a simple reduction in material and BOS costs. Corrugating the modules themselves can provide enough structural advantage to enable such a cost reduction, particularly as it negates the need for framing and tracking in some examples.

Detailed cost studies by the National Renewable Energy Laboratory (NREL) illustrate the potential cost advantages in module manufacturing. Current costs include 2.2c/W for 3.2 mm glass components, and 2.5c/W for aluminum framing (and sealing) process. Due to the more optimal use of material that corrugation provides in some embodiments, various examples can realize a 2-4× reduction in glass weight and total elimination of aluminum framing leading to a cost reduction of 3.6-4.2c/W per module from a 35-45c/W baseline. This can be a desirable 9-11% potential reduction in module cost in some embodiments, not including shipping weight and size advantages. Labor costs, in various examples, can be reduced by using larger panels that can still be lifted and maneuvered by a single worker due to weight savings. Simplification of racking can lead to further cost reductions by eliminating installation steps. In some embodiments, 10-20 degree corrugations can include about 1-6% extra cells, amounting to an increased cost of 0.2-1.2c/W in the solar module 110, which in various examples, can be more than compensated for by the extra power production over the lifespan.

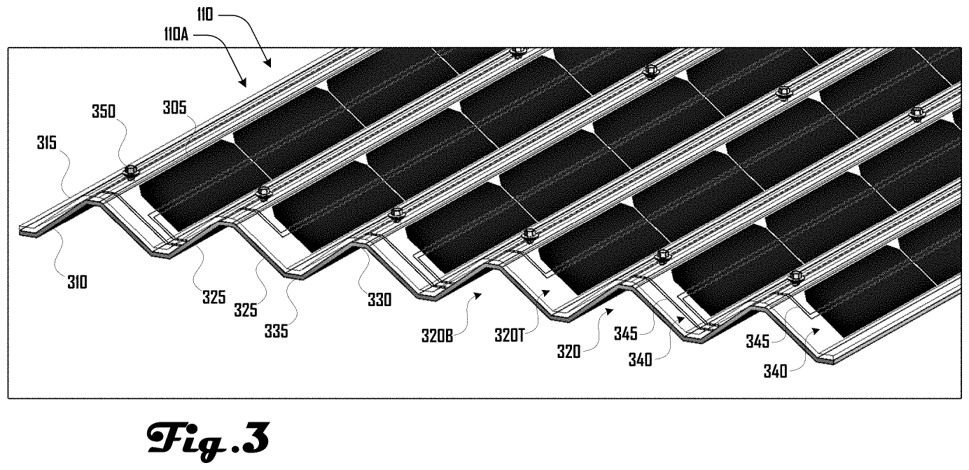

For example, FIG. 3 illustrates one example embodiment 110A of a corrugated solar module 110 that comprises a plurality of solar cells 305 disposed between a substructure 310 and a top layer 315. In various embodiments, the substructure 310 can comprise various suitable materials including plastic, glass, metal, or the like. In various embodiments, the top layer can comprise various suitable transparent or translucent materials such as plastic, glass, or the like (e.g., thermoforming plastic or slumped glass).

As shown in the example embodiment 110A of FIG. 3, the solar module 110 can be corrugated via an undulating structure of the solar module 110 that defines a plurality of alternating concave top channels 320T and bottom channels 320B that extend between opposing ends along parallel axes. For example, a given bottom channel 320B can be defined by first and second sidewalls 325 extending from a cap 330, and a given top channel 320T can be defined by first and second sidewalls 325 extending from a base 335.

As shown in the example of FIG. 3, the sidewalls 325, caps 330 and bases 335 can be substantially planar with the sidewalls 325 extending from the caps 330 and bases 335 at 1350 such that planes of symmetry extend perpendicularly through the caps 330 and bases 335, which are parallel to the parallel axes of the top channels 320T and bottom channels 320B. In various embodiments, the sidewalls 325 can have the same width as each other; the caps 330 can have the same width as each other; the bases 335 can have the same width as each other; the caps 330 and bases 335 can all have the width as each other; and the caps 330 and bases 335 can have a smaller width than the width of the sidewalls 325.

In various embodiments, faces of the caps 330 can be disposed in a common plane that can be perpendicular to the planes of symmetry of the caps 330, bases 335 and/or parallel axes of the top channels 320T and bottom channels 320B. In various embodiments, faces of the bases 335 can be disposed in a common plane that can be perpendicular to the planes of symmetry of the caps 330, bases 335 and/or parallel axes of the top channels 320T and bottom channels 320B.

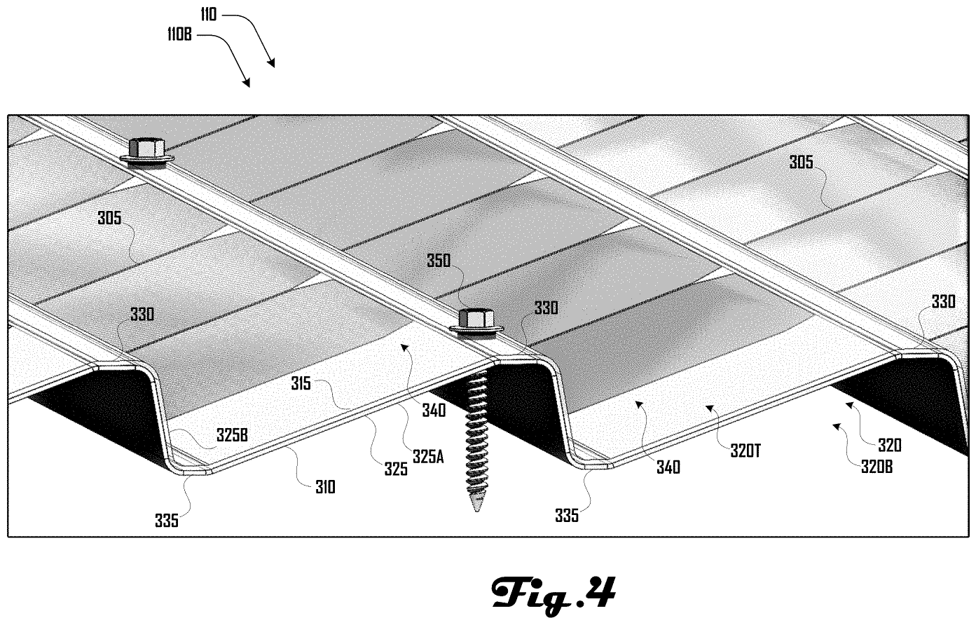

Further embodiments can be configured in various suitable ways and the example 110A of FIG. 3 should not be construed as limiting. For example, the sidewalls 325 can extend from the caps 330 and/or bases 335 at various suitable angles such as 90°, 95°, 100°, 105°, 110°, 115°, 120°, 125°, 130°, 135°, 140°, 145°, 150°, 155°, 160°, 165°, 170°, 175°, 180°, or the like, including within ranges within such example values. Additionally, as discussed in further examples herein, in some embodiments (see e.g., the embodiment 110B of FIG. 4), opposing sidewalls 325 can extend from caps 330 and bases 335 at different angles, including the example angles or within the example ranges discussed above. Additionally, in various embodiments, opposing sidewalls 325 extending from caps 330 and bases 335 can have different widths.

Returning to FIG. 3, the plurality of solar cells 305 can be disposed in a plurality of cell rows 340, with each cell row 340 disposed on a top face of a respective sidewall 325 (without cells 305 disposed on bottom faces of the sidewalls 325). In various embodiments, the cell rows 340 can be 1×N rows of cells 305, where the width of the cells 305 of the rows 340 extend the full width of the sidewall 325 or substantially the full width of the sidewalls 325. In various embodiments, N can be any suitable number of cells 305, including 1, 2, 3, 4, 5, 6, 7, 8, 9, 10, 15, 20, 25, 30, 35, 40, 45, 50, 75, 100, 200, 500, 1000, or the like. Additionally, in some embodiments, a plurality of 1×N rows can be disposed on a given sidewall 325.

As shown in the example of FIG. 3 solar cells 305 of a given cell row 340 can be operably connected via electrical lines 345 extending between the cells 305 of the cell row 340. In various embodiments, adjacent cell rows 340 can be operably coupled via electrical lines 345 that extend over caps 330 and/or bases 335 only at one or both opposing ends of the solar module 110.

As discussed herein, solar modules 110 can be coupled to a roof of a building 101 (see e.g., FIGS. 1 and 2) in various suitable ways. For example, as shown in the example embodiment 110A of FIG. 3, solar modules 110 can be coupled to various surfaces, or other locations via a plurality of fasteners 350 (e.g., screws, bolts, or the like) that extend through caps 330 of the solar modules 110, along the length of the caps 330. In some examples, fasteners 350 can extend through the caps 330 and/or bases 335 or other suitable locations of the solar modules 110.

Corrugated solar modules 110 can be installed in some embodiments such that mounting edges overlap. This configuration in various examples can ensure full coverage by the roof, such as at the seams. In some such instances, a butyl adhesive sealing tape, or the like, can be pre-installed onto a hydrophobic layer of the overlapped areas of the solar modules 110 so as to provide ingress protection when penetrating the module(s) 110 with a fastener 350, or the like. The hydrophobic coating can prevent water or moisture from collecting at the overlapping area.

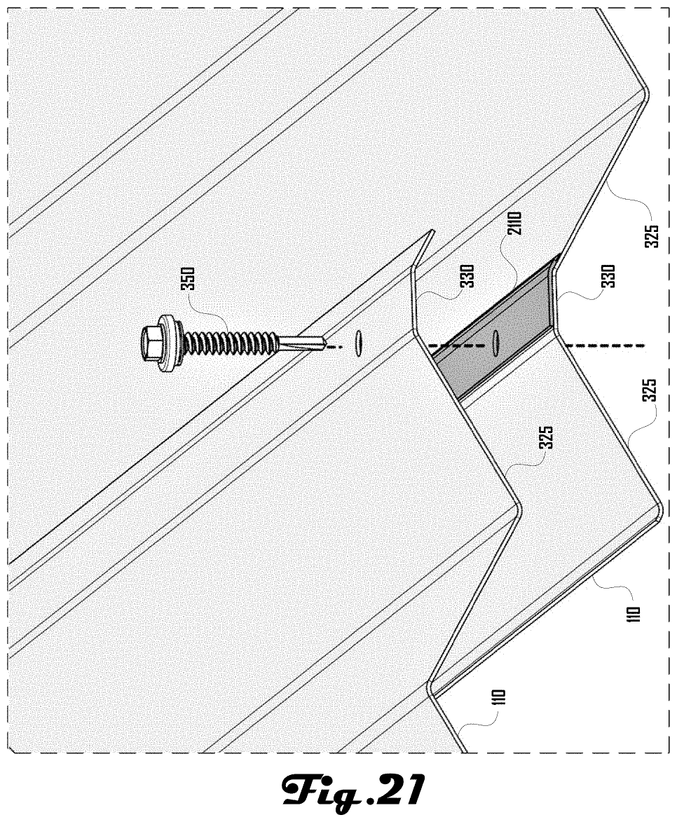

For example, FIG. 21 illustrates an example embodiment where a pair of solar modules 110 are coupled at an overlapping area with a seal 2110 between the modules 110. Specifically, a top module 110 can be disposed over a bottom module 110 at corresponding caps 330 and sidewalls 325 with a seal 2110 along the cap 330 of the bottom module 110 engaging the bottom of the cap 330 of the top module 110 to generate a seal between the modules 110. A fastener 350 can extend through the caps 330 of the modules 110 to couple the modules 110 to a structure such as a roof of a building.

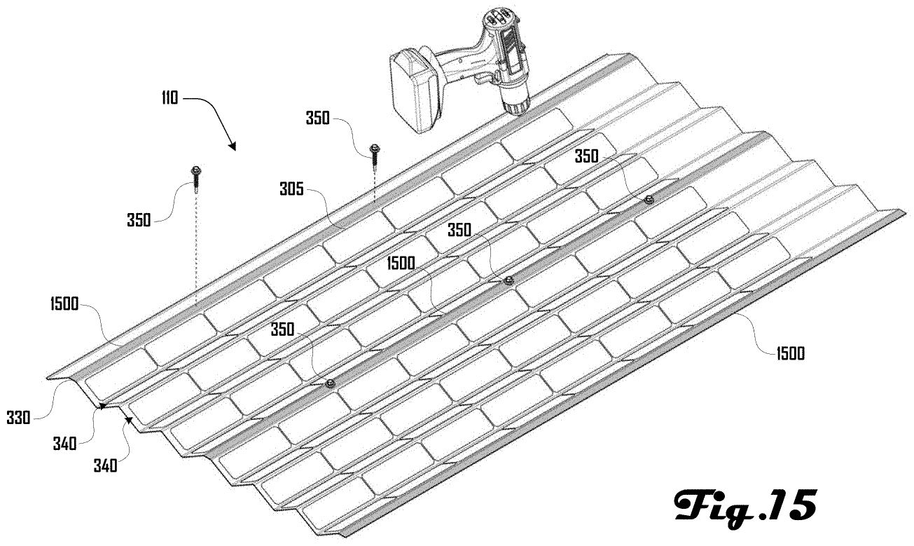

In some embodiments, solar modules 110 can have an area demarcated for placement and mounting of fasteners in the form of strips along the solar module 110. For example, FIG. 15 illustrates an example of a solar module 110 comprising a plurality of fastener strips 1500 disposed along caps 330 of the solar module 110 with fasteners 350 installed or being installed at the fastener strips 1500. In the example of FIG. 15, the caps 330 having fastener strips 1500 are planar, whereas the caps 330 without fastener strips 1500 can be pointed and substantially non-planar. Such a configuration can be desirable to maximize surface area of solar cells 305 while also providing areas where fasteners 305 can be used to install the solar module 110. In some embodiments, fastener strips 1500 can be disposed on every cap 330, every other cap 330, every third cap 330, every fourth cap 330, every fifth cap 330, or the like. In some embodiments, such fastener strips 1500 can provide greater flexibility for installation on any configuration of roof structure (e.g., presence and placement of purlins) while keeping the electrical and photovoltaics safe.

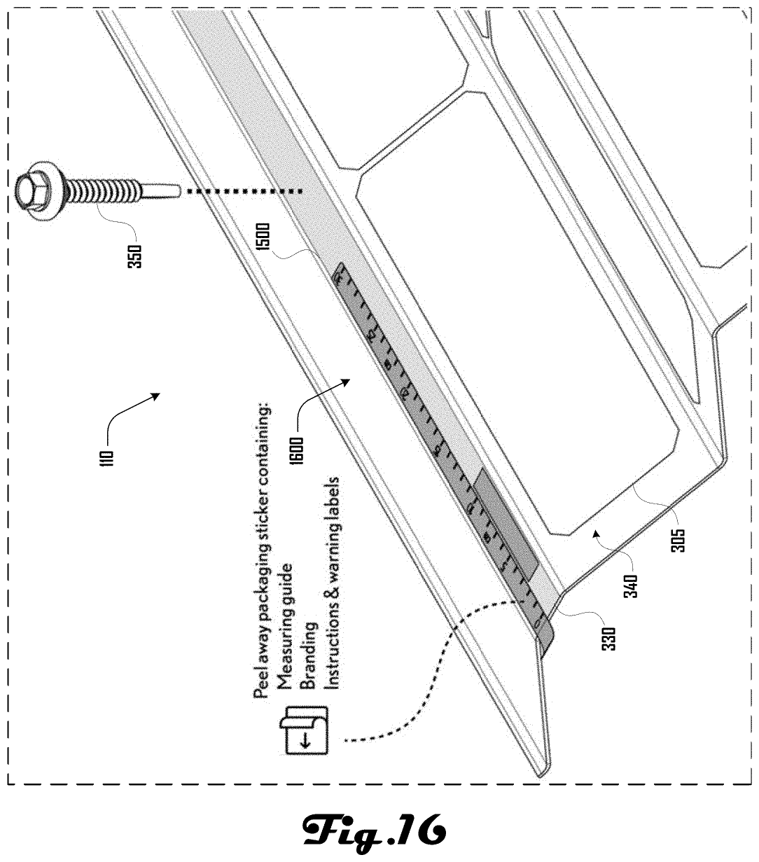

In some embodiments, fastener strips 1500 can comprise a removable, disposable adhesive label that includes measurement indication for easier mounting fastener placement. For example, FIG. 16 illustrates an example of a solar module 110 comprising a fastener strip 1500 that includes a label 1600 that can include a measuring guide, branding, installation instructions, warning label, and the like.

Turning to FIG. 4, another example embodiment 110B of a corrugated solar module 110 that comprises a plurality of solar cells 305 disposed between a substructure 310 and a top layer 315. In various embodiments, the substructure 310 can comprise various suitable materials including plastic, glass, metal, or the like. In various embodiments, the top layer can comprise various suitable transparent or translucent materials such as plastic, glass, or the like (e.g., thermoforming plastic or slumped glass).

As shown in the example embodiment 110B of FIG. 4, the solar module 110 can be corrugated via an undulating structure of the solar module 110 that defines a plurality of alternating concave top channels 320T and bottom channels 320B that extend between opposing ends along parallel axes. For example, a given bottom channel 320B can be defined by first and second sidewalls 325A, 325B extending from a cap 330, and a given top channel 320T can be defined by first and second sidewalls 325A, 325B extending from a base 335.

As shown in the example of FIG. 3, portions of the sidewalls 325, caps 330 and bases 335 can be substantially planar with the sidewalls 325 extending from the caps 330 and bases 335 at different angles via an angular or curved connection between the caps 330, bases 335 and sidewalls 325. In the example of FIG. 4, the first sidewalls 325A can be of the same width as each other and can have a greater width than the width of the second sidewalls 325B. Accordingly, in the example 110B of FIG. 4, a plane of symmetry is absent through the caps 330 and bases 335 (e.g., in contrast to the example of FIG. 3 where a plane of symmetry is present through the caps 330 and bases 335). Additionally, in various embodiments, cell rows 340 can be disposed on the first sidewalls 325A and can be absent on the second sidewalls 325B (e.g., in contrast to the example of FIG. 3 where cell rows 340 are disposed on both sidewalls 325).

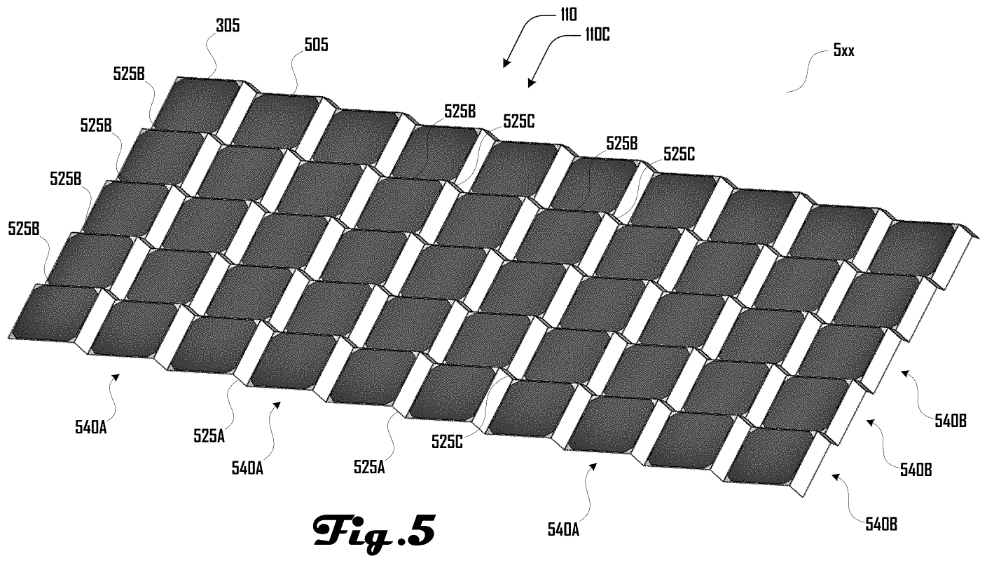

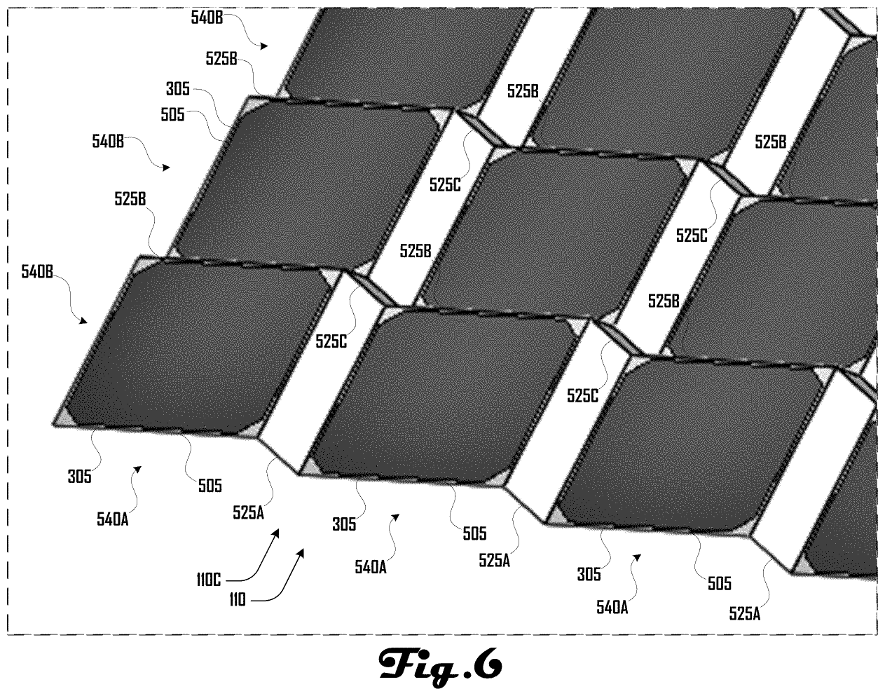

Turning to FIGS. 5 and 6 an example embodiment 110C of a terraced solar module 110 is illustrated, which comprises a plurality of solar cells 305 disposed in a terraced configuration, where one or more solar cells 305 are disposed on respective terrace plates 505, with the terrace plates 505 being terraced from each other via first and second primary sidewalls 525A, 525B and an offset sidewall 525C.

The terrace plates 505 can be disposed in an array of terrace columns 540A and terrace rows 540B. For example, in the embodiment 110C of FIGS. 5 and 6, the terrace columns 540A can be construed to be stepping down from the front edge toward the rear edge via the second primary sidewalls 525B and the terrace rows 540B can be construed to be stepping down from the left edge toward the right edge via the first primary sidewalls 525A. Terrace plates 505 of the terrace columns 540A can be offset from each other via the offset sidewall 525B. In some embodiments, each of the terrace plates 505 can be disposed in a different parallel plane or different sets of a plurality of terrace plates 505 can be disposed in different common planes in various suitable ways.

Additionally, while the example 110C of FIGS. 5 and 6 illustrate a plurality of square rectangular terrace plates 505, further embodiments can include terrace plates 505 of various suitable shapes, including polygons such as a triangle, square, rectangle, pentagon, hexagon, heptagon, octagon, or the like. In some embodiments, the terrace plates 505 can be the same shape or different shapes. Also, in some embodiments, the terrace plates 505 can have single cell solar cell 305 or can have any suitable plurality of solar cells 305 including an array of X by Y cells, where X and Y can be any suitable integer such as 1, 2, 3, 4, 5, 6, 7, 8, 9, 10, 15, 20, 25, 50, 100, or the like. X and Y can be the same or different in various embodiments.

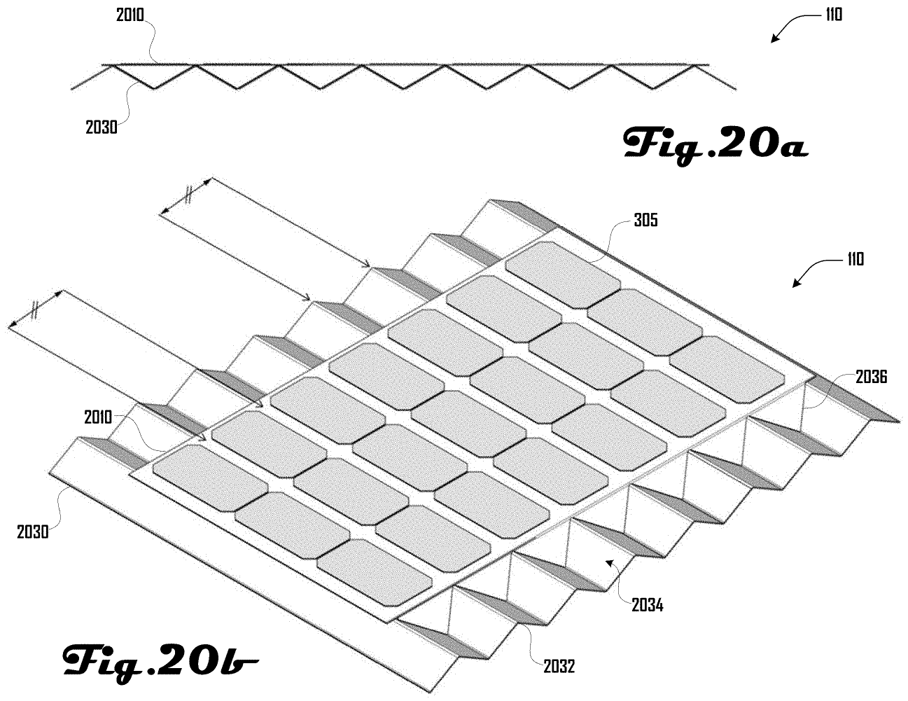

A building-integrated photovoltaics (BIPV) module or solar module 110 of some embodiments can be structurally optimized such that a frameless flat photovoltaic panel is mounted directly to a corrugated substrate mechanically, adhesively, or otherwise. Such a flat panel in some examples can be constructed such that the channels between the lower-corrugated or otherwise-structural unit, and the photovoltaic top-sheet are closed, preventing ingress of water and other debris. For example, FIGS. 20a and 20b illustrate an example of a solar module comprising a planar photovoltaic panel 2010 disposed on a corrugated substrate 2030. Specifically, the planar photovoltaic panel 2010 is disposed on tops 2032 of corrugations 2034 of the corrugated substrate 2030 with plugs 2036 filling openings at ends of the photovoltaic panel 2010 between corrugations 2034.

Some instantiations can include bifacial solar modules 110, which can feature solar cells 305 on both sides of the module 110, which in various examples can be used to generate more energy from refracted light. A bifacial solar module in some examples can employ transparent layers (e.g., the substrate layer 750) which can allow additional sunlight transmission through the solar module 110 for structures such as greenhouses or for other use cases that may benefit from additional ingress of light. This application is not necessarily limited to roofing and bifacial solar modules 110 can be applied to walls or any other fixture that may benefit from solar generation.

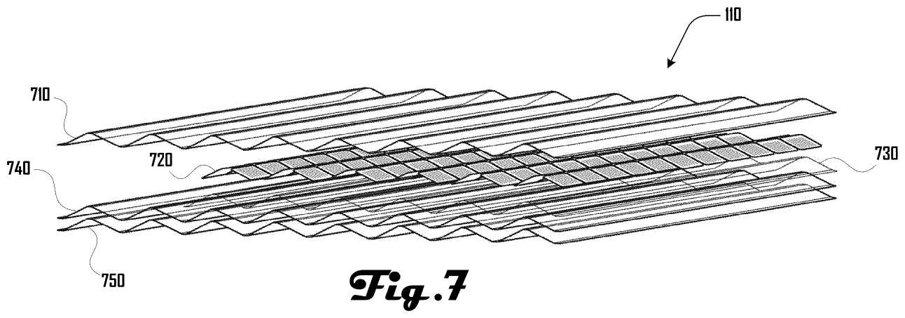

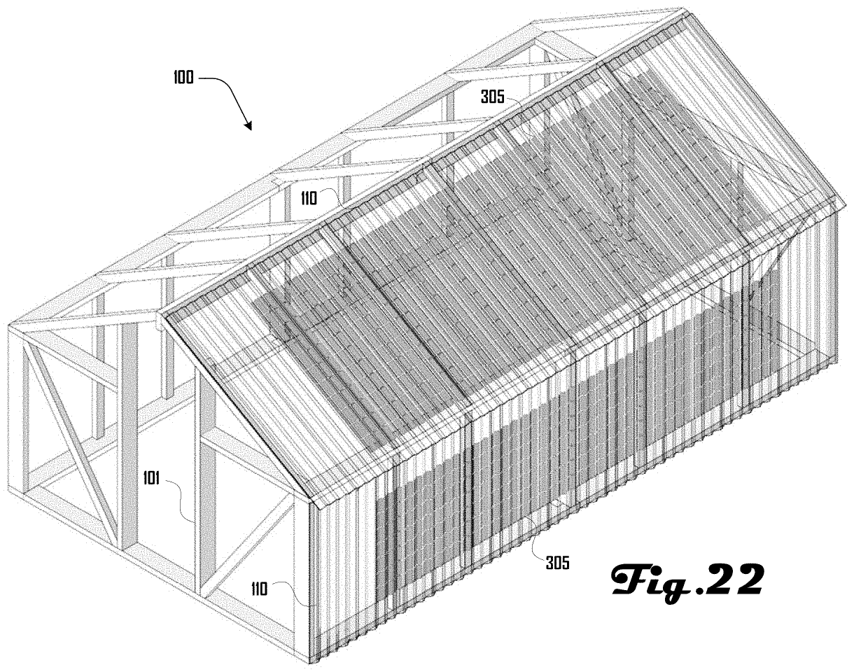

For example, FIG. 22 illustrates an example of a solar system 100 comprising a plurality of solar modules 110 coupled to a building 101, including the roof and a wall of the building 101. In this example of FIG. 22, the solar modules 110 are shown being substantially transparent or translucent, which can allow for light transmission through the solar modules 110. The solar modules 110 in such an example can comprise solar cells 305 on both faces of the solar modules 110 such that light exposure on the top and bottom faces of the solar modules 110 can generate electric power. In some examples, the solar modules 110 can be substantially transparent or translucent aside from the solar cells 305. For example, a top layer 710, substrate 750 (see FIG. 7) can be transparent or translucent to allow for light transmission through such elements.

Solar modules 110 can be made of a plurality of layers in some embodiments. For example, FIG. 7 illustrates an example of a solar module 110 comprising a plurality of layers including a top layer 710; a solar cell net or photovoltaic net 720; a wiring system 730, an encapsulant layer 740 and a substructure 750. In some embodiments, the top layer can comprise thermoforming plastic, slumped glass, or the like. In some embodiments, the encapsulant layer 740 can comprise an ethylene vinyl acetate (EVA) plastic film, polyvinyl butyral (PVB), thermoplastic polyurethane (TPU), or the like. In some embodiments, the substructure can comprise plastic, glass, metal, or the like. Further embodiments can have any suitable additional layer or fewer layers. Additionally, the example ordering of the layers in the embodiment of FIG. 7 should not be construed as limiting and layers can be stacked in any suitable way. In various embodiments, a solar module 110 can be constructed with a layered corrugated substrate 750. In such a configuration, different layers can have corrugations in different directions. In some examples, this can permit a larger surface area for photovoltaic cells 305 while still preserving substrate structural integrity.

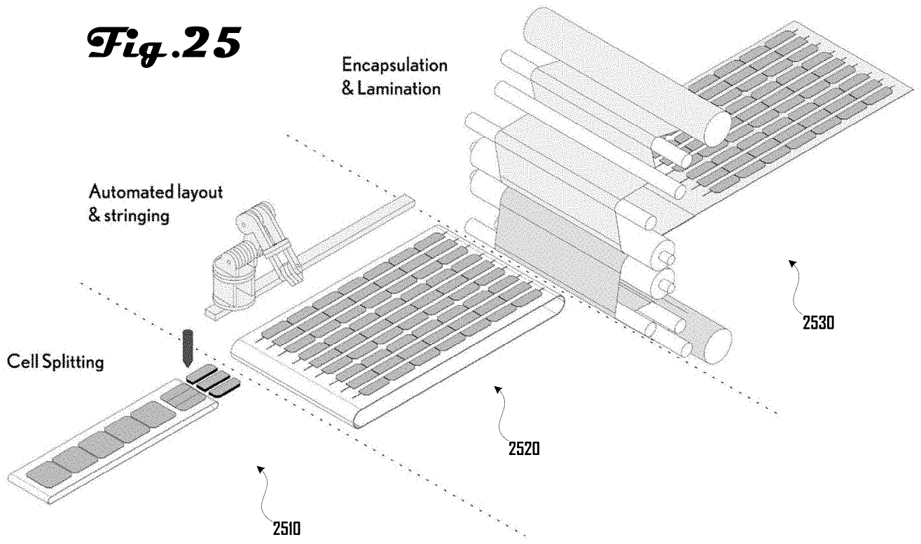

In some embodiments, solar modules 110 can be manufactured by a nearly fully automated streamlined process. FIG. 25 illustrates one example of a method of manufacturing a solar module 110. In a first example step 2510, a solar cell is precisely split using a CNC fiber laser or other suitable method. These split cells can be placed onto a bed into a layout and soldered into strings by an automated process as shown in the second example step 2520. In a third example step 2530, the strings can be fed into a multi-roll lamination and encapsulation machine, which can protect and isolates the photovoltaics from the environment. Such a generated photovoltaic sheet can be adhesively bonded to a flat metal substrate, which can be coated or otherwise processed for protection from the elements. The flat photovoltaic panel can then be structurally optimized by roll forming bends, corrugations, or other geometry such that the panel is no longer flat and is formed into a corrugated solar module 110 (e.g., structurally optimized for uses such as roofing or siding).

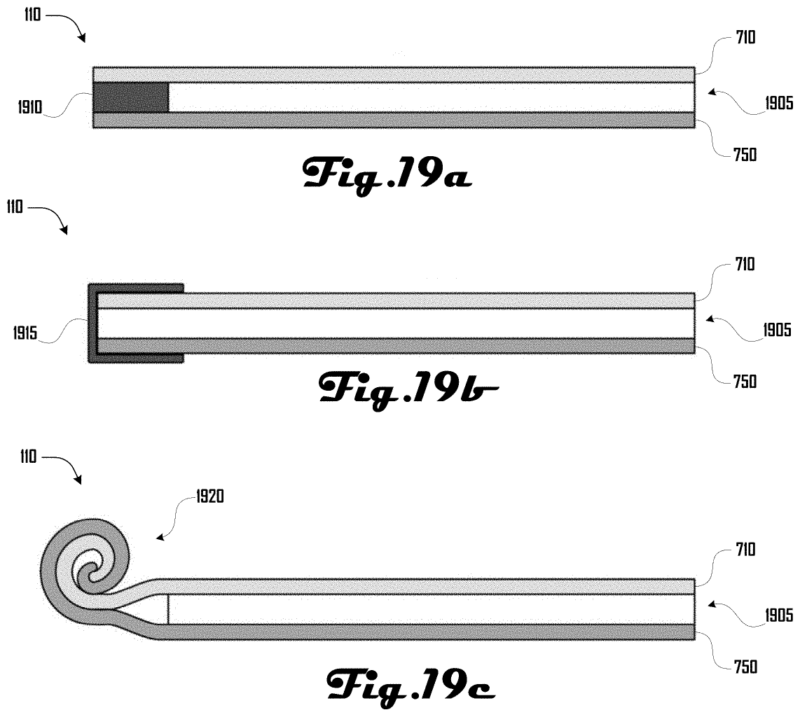

In various embodiments, one or more edges of a solar module 110 can be sealed from environmental ingress protection by one or more suitable methods such as using an adhesive sealing tape, an adhesive U-shaped edge trim, by rolling the edge on itself to create a watertight seal, or the like. Such methods can provide ingress protection of environmentally sensitive materials such as the encapsulants, electrical components, such as cells and wiring, and the like. For example, FIGS. 19a, 19b and 19c illustrate example methods of sealing an end of a solar module 110 comprising internal elements 1905 (e.g., a solar cell net or photovoltaic net 720; a wiring system 730, an encapsulant layer 740 as shown in FIG. 7, or the like) disposed between a top layer 710 and a substrate layer 750.

For example, FIG. 19a illustrates an example embodiment where a seal 1910 (e.g., sealing tape, or the like) is disposed at an end of a solar module 720 between the top layer 710 and the substrate layer 750 to provide a seal protecting the internal elements 1905 of the solar module 110. FIG. 19b illustrates an example of a U-seal 1915 disposed surrounding an end of a solar module 720, including surrounding an end of the top layer 710, the substrate layer 750 and the internal elements 1905 to provide a seal protecting the internal elements 1905 of the solar module.

FIG. 19c illustrates an example embodiment comprising a rolled edge 1920 at an end of a solar module 720 defined by rolled ends of the top layer 710 and the substrate layer 750 that provide a seal protecting the internal elements 1905 of the solar module 110. In such an example, the top layer 710 and the substrate layer 750 can be longer or extend past and end of the internal elements 1905 such that the top layer 710 and the substrate layer 750 can be rolled together toward the substrate layer 750 to generate a seal between the top layer 710 and substrate layer 750 to protect the internal elements 1905. In some embodiments, such rolling can generate a cavity between the top layer 710, the substrate layer 750 and internal elements 1905 at the end of the solar module 110. In further embodiments, the top layer 710 and the substrate layer 750 can be coupled in various suitable ways including crimping, welding, an adhesive or the like.

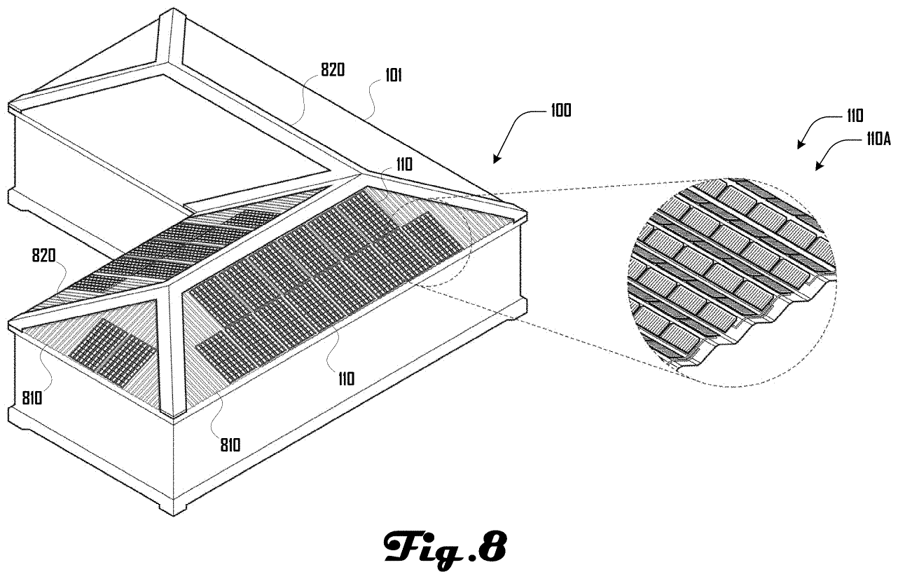

Some embodiments can focus on integration of solar modules 110 with existing and market dominating silicon technologies as opposed to other roofing solutions that use thin film technologies. Various embodiments can include fabricating corrugated roofing panels with solar cells 305 incorporated structurally into the panel corrugations themselves. This design in various examples can allow for significant structural optimization due to the mechanical stiffness and superiority of corrugations, as well as integrating seamlessly with common rooftop architectural vernaculars. In addition to the building-integrated photovoltaics (BIPV) hardware development, further developments can include best installation standards and practices for the roofing hardware itself and its integration with home roofing and electrical systems. Various embodiments can include benefits to the residential solar market, including one or more of: 1) Time savings in new home construction when renewable energy is a planned feature, 2) System wide cost reduction when a roof is at end-of-life, 3) Accelerated residential clean energy adoption, 4) Reduction in solar installation costs, helping to reverse current debilitating trends for installers in the market, 5) Approachable solar aesthetics in an already growing roofing market, and 6) elimination of BOS components and complexity including racking and framing. FIGS. 1 and 2 show how home aesthetics are preserved with some embodiments of a solar integrated roofing system, as FIGS. 8-10 provide a more granular look at the roofing hardware and FIGS. 15 and 16 provide examples of strength to weight ratio in accordance with some examples.

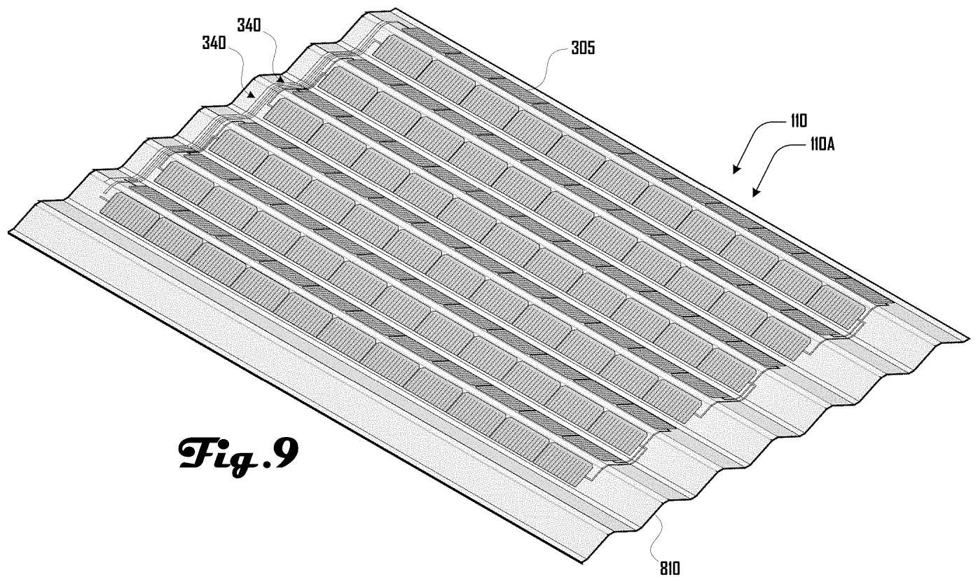

For example, FIG. 8 illustrates an example of a solar system 100 comprising a plurality of solar modules 110 disposed on the roof of a building 101 over or along with a corrugated roofing material 810 with flashing being disposed on the roof of the building 101 as well. FIG. 9 illustrates an example of an embodiment 110A of a corrugated solar module 110 being disposed on and corresponding with a corrugated roofing material 810.

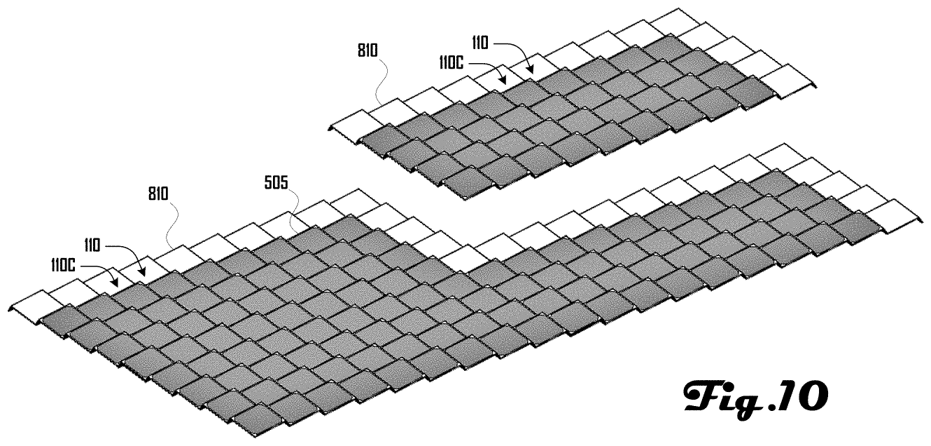

In some embodiments, residential roofs will be able to make use of the largest available solar area while maintaining use of standard roofing hardware for installation and suitable features (e.g., corrugated troughs) can be utilized in some embodiments for fastener placement while edges (e.g., flat edges, corrugated edges, terraced edges, or the like) of solar modules 110 and/or roofing material 810 can overlap with neighboring panels. For example, FIG. 10 illustrates an example embodiment of a solar system 100 comprising a plurality of terraced solar modules 110 disposed on roofing material 810, with a portion of some peripheral edges of solar modules 110 and/or roofing material 810 being configured to overlap and couple together. For example, the roofing material 810 can have terracing matching terracing of the solar modules 110 so adjacent pieces can fit together on a roof of a building or other location.

Design loads for existing photovoltaic systems can include one or more of: 1) the wind load or fastening loads to the rooftop, 2) the point loads for impact (e.g., hail), and 3) the bending stiffness or structural load across a solar module 110. A 4th design load can be the installation and maintenance loads implied by the roof needing to be walked upon. Corrugations can improve some or all of these loads substantially in some embodiments; for example, by using the lamination layers to provide both encapsulation and structure, rather than in some examples of solar panels, where bulky aluminum frames support glass, photovoltaic, and encapsulation layers. The corrugation pitch of the panels can be designed in some embodiments to carry the load of a worker during installation, when spanning standard rafter and purlin spacing. The structural behavior of such corrugated panels can allow large distances to be spanned by thin gauge material in some embodiments. For instance, an 18 gauge cold formed steel sine wave corrugated panel can support the weight of a 215 lb. worker over a 4 foot span of 1 foot width, while only weighing 10 pounds and costing $5. Additional corrugations can also be incorporated in some examples to increase load carrying capacity. Further embodiments can include corrugations in multiple axes to vastly improve stiffness.

For example, as discussed herein FIG. 7 shows an expanded view of the materials used in one example embodiment of a sandwiched corrugated panel. An internal material selection process can define specific materials for technical requirements including electrical isolation and solar cell encapsulation through structural, electrical, and reliability testing. Some embodiments can include plastic-fronted modified “flexible” modules from Sunpower, and some embodiments can include polymer and glass variants.

Alternative solar technologies exist within other roofing genres outside of metal, the Tesla solar shingle being a popular example. While some conventional solar roofing technologies can be aesthetically pleasing, these solar roofing types can be cost prohibitive to medium to low income homeowners; for example, a Tesla solar roof holds the price tag of $44,000 for 2,000 sq ft of roofing. This price can be reduced by state and local incentives and tax credits, though those are still based on percentages of a price tag that is already unapproachable to low to middle income households. In addition to its affordability, solar shingle installation in some examples can require an entirely new roof structure with installation. Larger scale corrugated panels of some embodiments can be installed to sync with other corrugated roofing that is in place and integrate with the existing roofing substructure. The lightweight solution in various examples can negate a need for additional structural reinforcement.

A common pain point in various solar power systems is construction and installation, including unity with the home electrical system. Major solar installers are consistently taking profit loss due to fierce competition and early upfront investment requirements prior to job completion. When paired with roofing, solar installation can be performed by experts in the construction industry.

Coming up with a new way of making modules that replace existing glass modules can have a large potential impact. With such a large market and aggressive funding, development, and manufacturing options become available ($1/W=1$t/TW and global PV requirement is perhaps 50 TW).

Solar panels can cost as little as $30/m², and glass costs can be significant, with base glass costs being as little as $5/m² (e.g., 1 layer of ˜3 mm glass). The glass can dominate the weight of a conventional solar panel (e.g., typically over half). Corrugated steel cost can be similar to this order, depending on thickness—more expensive per kilogram, but there is less of it. However corrugated steel can be around half the weight in some examples, which can have substantial benefits. Eliminating the frame of a convention solar panel can also be desirable in various examples.

Solar panels can be around 20 kg each (˜1 m×1.5 m), and being able to reduce this can have huge benefits to logistics (cost or transport) and also installation—panel size can be limited by one person lift capacity on a roof. Accordingly, some embodiments of corrugated solar panels can have larger panel size compared to conventional solar panels given the reduced weight of corrugated solar panels in some examples.

Conventional solar modules can be ˜40-50 mm thick, which suggests they are volume constrained when packed in a shipping container. Being able to go thinner with corrugated solar panels (e.g., as packed, in a tessellated fashion) can be a huge logistics win—more panels can pack on a pallet and in a shipping container.

In some embodiments, glass covered modules can use micro corrugating of the surface to better accept low incidence light.

Colorbond roofing can be 0.42-0.48 mm thick, and can be as little as 5 kg/m². This can be half the mass of traditional panels/modules in some examples—a huge win.

While specific example embodiments (e.g., 110A, 110B, 110C) of corrugated and terraced solar modules 110 are shown and described herein, these examples should not be construed as being limiting and a wide variety of different configurations are within the scope and spirit of the present disclosure. For example, some embodiments can comprise trapezoidal, sinusoidal or asymmetric corrugations. Additionally, in some embodiments solar cells 305 may or may not be corrugated, and if so, can be corrugated any suitable amount. Additionally, in some embodiments, it can be desirable for corrugated solar cells 305 to be curved (e.g., with concave or convex outward curvature in some examples). In some embodiments, solar modules 110 or portions thereof can be configured to be strong enough for human users to walk on them or can be configured to not be walked on.

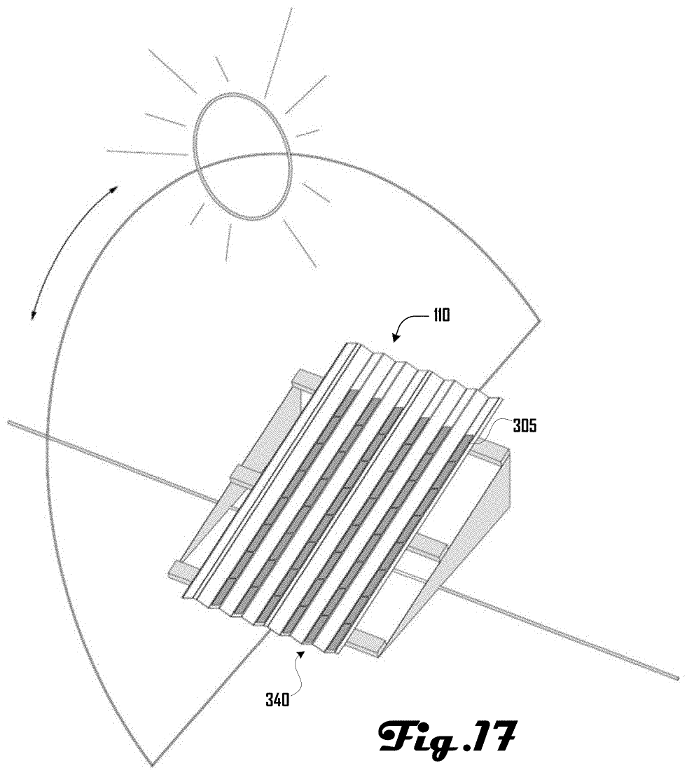

Additionally, in various embodiments, configuration of corrugations and/or terracing can be configured based on an intended mounting angle, sun exposure conditions (e.g., local or geographic differences), location on a roof or other structure (e.g., facing north, south, east or west). For example, corrugations and/or terracing can be configured based on intended application to flat roofs, roofs of various angles, or application to vertical surfaces. Additionally, in some embodiments, corrugations and/or terracing can be configured for being applied in the northern hemisphere, southern hemisphere, or the like. Also, in further embodiments, corrugations and/or terracing can be configured differently for solar modules 110 being mounded facing north, facing south, facing east, facing west, or the like. For example, FIG. 17 illustrates an example of a solar module 110 mounted (e.g., on a roof of a building) such that corrugations and solar cells 305 are disposed parallel to the path of the sun.

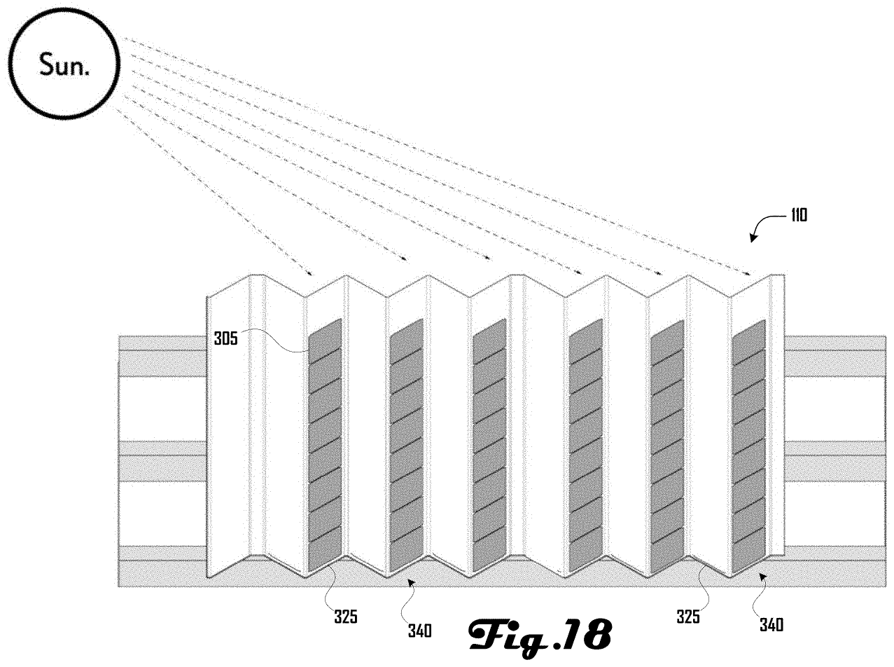

In some embodiments, a solar module 110 can have photovoltaic cells 305 all facing in the same direction. The photovoltaic cells 305 can be mounted to a corrugated face such that the effective photovoltaic area remains at an angle from the mounting surface of the solar module 110, such as a rooftop. In various examples, such a configuration can allow installation of rooftop solar on roof angles or pitches not traditionally ideal for solar production, as the angle of the corrugations can positions the solar cells 305 for maximum UV exposure. For example, FIGS. 17 and 18 illustrate example embodiments of solar modules 110 having rows 340 of solar cells 305 disposed on only one side of corrugations (e.g., on every other sidewall 325) with the solar modules 110 oriented relative to the angle of the path of the sun where the solar modules are disposed.

Aluminum can be used in various embodiments of corrugated solar panels. For example, use of aluminum can avoid corrosion and can reduce weight, which can improve logistics and installation.

Solar cell area to total roof area ratio can be an important metric on which traditional rooftop solar installations do poorly. This can affect total installed power and balance of system costs. This metric can be maximized or improved with some embodiments of corrugated solar modules 110.

Striving for full cell coverage, in some examples the corrugations can be triangular instead of trapezoidal, with nail holes present within the gaps produced by rounded corners of the solar modules 110, or in some examples, the solar modules 110 can be directly shaped to allow space for a nail while little compromising total area of the solar module 110.

Various embodiments can include systems and methods to make the solar modules 110 easier to cut down to size in the field without compromising electrical integrity. For example, some embodiments enable solar modules 110 to be cut between the cells 305 or cell rows 340 through the electrical “wires” 345, with some examples including an insulating endcap.

In some embodiments, a foam core backing can be integrated, structural insulation panel style, which in some examples can increase strength, and some embodiments can spot weld a second corrugated substructure 310 to the back of a solar module 110 which can be perpendicularly aligned for much greater strength (e.g., providing added bending strength in the other axis)—this, in some examples would not need a frame.

Further embodiments can include corrugated solar modules 110 of odd shapes and/or sizes for filling in difficult to fill roof corners and short extensions to make up lengths can be made and standardized.

Low voltage can be advantageous in some embodiments. For example, under 50V to reduce regulatory constraints and allow safe non-expert installation and repair.

Shorting out the solar modules 110 to a metallic substrate can be a concern in some scenarios. The substrate 310 can be used as a ground in some cases.

Roofs can have corrugations aligned to allow for downward water flow, this will not always line up with the optimal north/south direction. Designs and layouts of some embodiments of corrugated solar panels 110 can be optimized with this in mind.

In some embodiments, the corrugated structure can be designed to be strong enough to be walked on. Design can be configured to enable it to fail gracefully, including with respect to electrical connections and individual cell failures.

Tight packing for shipping that enables more solar modules 110 per pallet and less packing material can be desirable in various embodiments. While corrugated solar modules 110 can interleave and pack tightly, this can present a challenge in some examples to integrate the electronics box to better enable this. Options can include going fully distributed/thin with the electronics and use low profile connectors. Cleanly connecting multiple modules together can be a challenge in some examples, such as where voltages and amperages vary. This can favor more localized power conditioning in some embodiments.

To win the manufacturing game, highly automated vertically integrated manufacturing can be employed, with multiple plants per continent. Speed of scaling can be desirable to achieve market dominance, and in some examples needs to be able to scale at around 50% per year or greater. Extreme throughputs with very small plant footprints can be desirable in some examples—for example, continuous flow high speed processes with minimal distance between processes. Going from raw material to delivered and paid for product in as little as a month can be desirable. Starting with coiled sheet instead of float glass can help with this in various examples. Manufacturing plants can be installed in as little as a few months in some embodiments. Also, manufacturing plants can go through multiple iterations/revisions per year initially in some embodiments.

Technology that can scale the fastest often wins in some examples—scale might get to lower cost faster than “better” technology (e.g., doubling production might typically reduce per unit costs by ˜20%—Wright's Law). Ability to scale faster than other technologies often is the innovation, and it can be hard to protect and maximize this without full vertical integration.

Material costs can vary in various embodiments, for example, 1×3.2 mm glass, say $4/m² and 8 kg/m², 0.5 mm Steel say 5.5 kg/m² and $4/m², 0.5 mm Aluminum say 2 kg/m² and $4/m². There is not a lot of cost difference here in this example—it can depend on details and secondary benefits like reduced weight (logistics and handling), no frame, etc. At $0.2/W, a solar panel might cost $30/m² so a $3 saving would be worth 10%. Given how cost sensitive this market has become this can be enough to dominate the market in some embodiments.

Corrugated glass and corrugated fiberglass/carbon can be present in some embodiments. Structural insulation panels (aluminum skins with a foam core, for example) can be present in some embodiments. The corrugated structural approach can be applied to a multitude of materials and material combinations.

About 10 years ago, module costs were much higher and glass costs proportionately less. This may help explain why a corrugated approach to solar modules 110 is not currently known in the art. Glass used to be proportionately low cost, flat, transparent, UV resistant, rigid/strong, long lived, etc., but these benefits are not as unique or critical as they once were. There are greater material, structural, and manufacturing options available now.

Corrugated one or more solar modules 110 can be supported at each end in some embodiments by tensile members that can comprise one or more of wires, wires ropes, polymer ropes, pultruded composites, and so forth, avoiding the need for heavy semi rigid structural supports in some examples. The corrugated solar modules 110 of some examples can be somewhat compliant in bending along the axis perpendicular to the corrugations, which can well match flex in the cable support. In the case of ground mounted solar arrays, the tensioned cables in some embodiments can be supported on fence posts that can comprise one or more of waratahs, helical/screw anchors, posts, and so forth, manufactured from any number of suitable materials including steel, aluminum, composites, and concrete. Numerous ground types are applicable including bare soil, pasture, gravel, concrete, a body of water, bed of a body of water, or the like. Fence posts for the tensile structure can be of varied lengths in some embodiments so as to facilitate angled panels that better capture available solar energy.

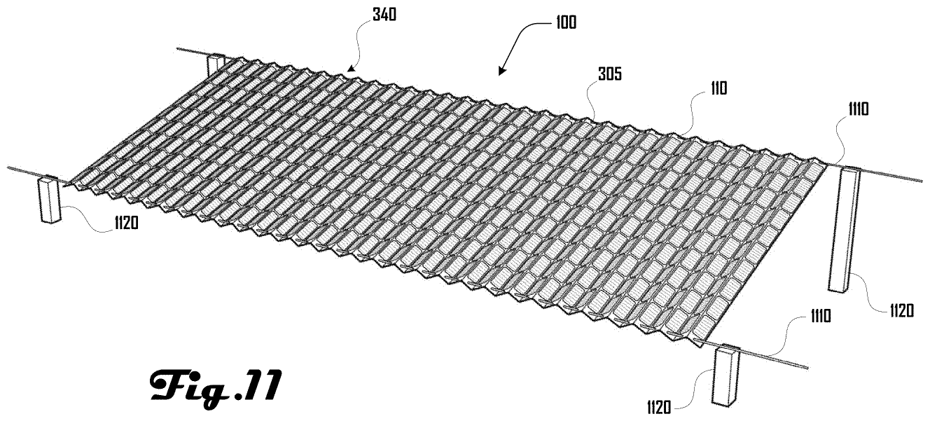

For example, FIG. 11 illustrates an example of a solar system 100 comprising one or more corrugated solar modules 110 having support bars 1110 extending through opposing edges of the one or more corrugated solar modules 110 and perpendicular to and axis of rows 340 of solar cells 305. The support bars 1110 can be configured to rigidly hold the one or more corrugated solar modules 110 in a planar configuration as shown in the example of FIG. 11.

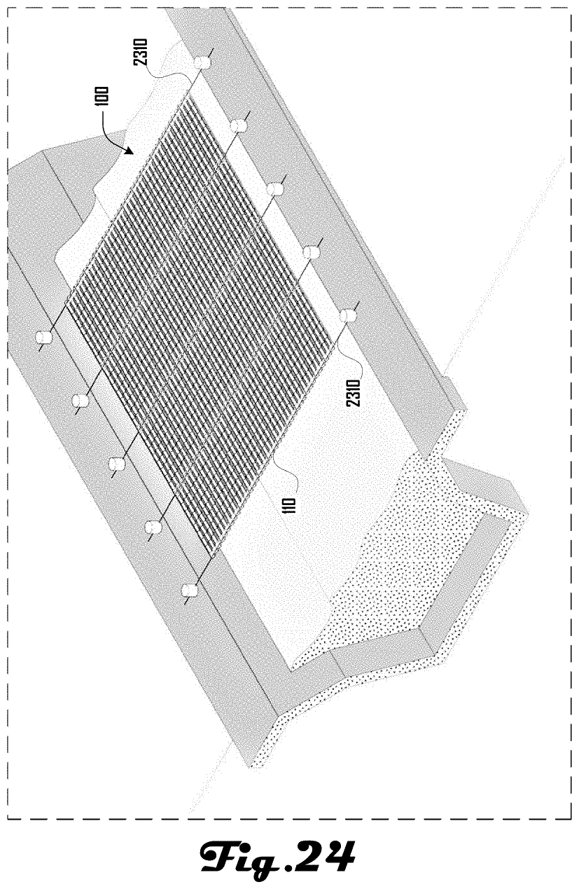

In some embodiments, such as the example of FIG. 11, a solar system 100 can be installed without fasteners using a combination of suspended support bars 1110 or steel cables and slotted grooves in corrugations of a solar module. Such grooves can be designed with a specific shape in various examples in order to fit, capture, and retain one or more solar modules 110. The support bars 1110 or suspended steel cable can be easily routed through the grooves of one or more solar modules 110 whilst under tension or suspended. In various embodiments, once routed, the weight of the solar modules 110 can retain the cable support bar 1110 in the slot, suspending the solar modules 110. Such suspended mounting technology can be utilized in a situation that calls for non-fastener technologies, such as over a canal, valley, or other such location. For example, FIG. 24 illustrates an example of a solar system 100 comprising a plurality of solar modules 110 suspended over a canal.

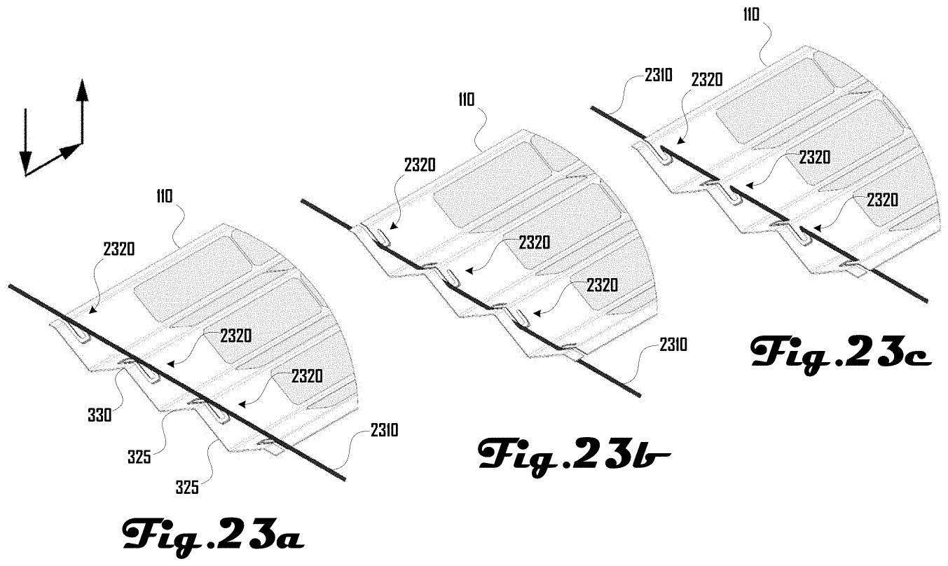

For example, FIGS. 23a, 23b and 23c illustrate an example of a support line 2310 (e.g., a bar, cable or the like), coupling with a plurality of slots 2320 in a solar module 110 such that the solar module 110 can be held or suspended by the support line 2310. Specifically, as shown in the example of FIGS. 23a, 23b and 23c a plurality of C-shaped slots 2320 can be defined by the cap 330 and portions of opposing sidewalls 325 extending from the cap 330. FIG. 23a illustrates the support line 2310 being positioned over the slots 2320 and FIG. 23b shows the support line 2310 positioned within a first portion of the slot 2320 and engaging the sidewalls 325 that define the slot 2320. The support line 2310 can be shifted within the slots 2320 toward the center of the solar module 110 and then the solar module 110 can be allowed to shift downward such that support line 2310 is held within a second portion of the slots 2320 as shown in FIG. 23c.

While the example of FIG. 11 illustrates the one or more corrugated solar modules 110 with the support bars 1110 extending through corrugations of the solar modules 110, in further examples, one or more solar modules 110 can rest on support bars 1110 or other suitable structure, be suspended from support bars 1110 or other suitable structure, or the like.

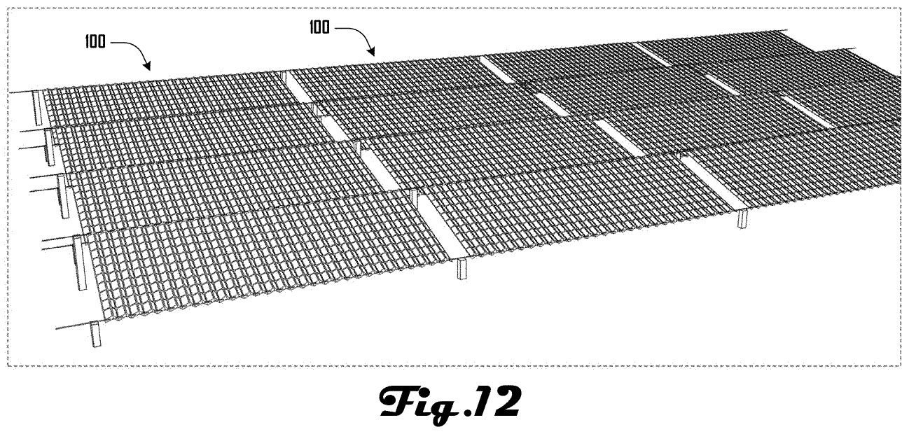

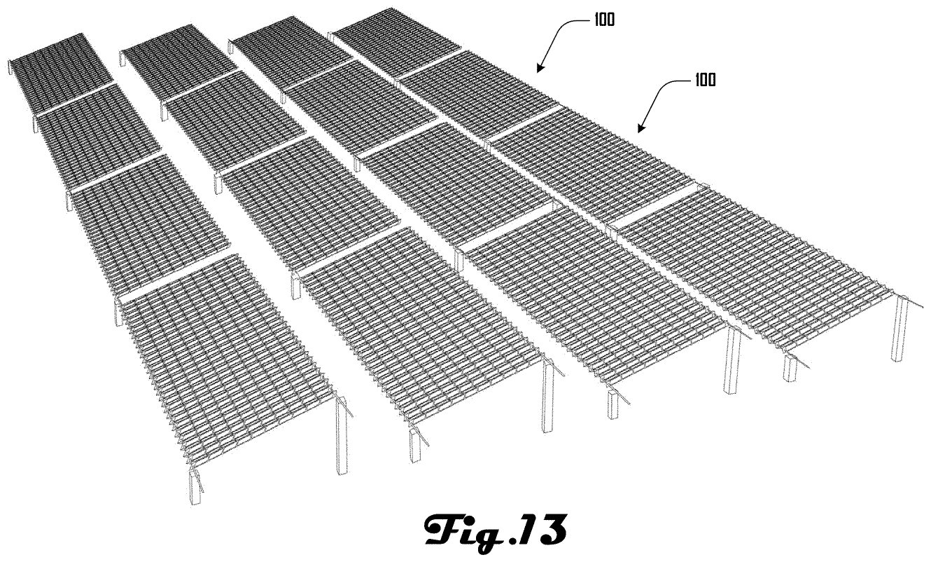

The support bars 1110 can be disposed on a plurality of posts 1120 that hold the one or more corrugated solar modules 110 at an angle as shown in the example of FIG. 11 or other suitable orientation based on the posts 1120 being the same and/or different lengths, or the like. A plurality of such solar systems can be grouped together in an array in some embodiments such as in the examples shown in FIGS. 12 and 13.

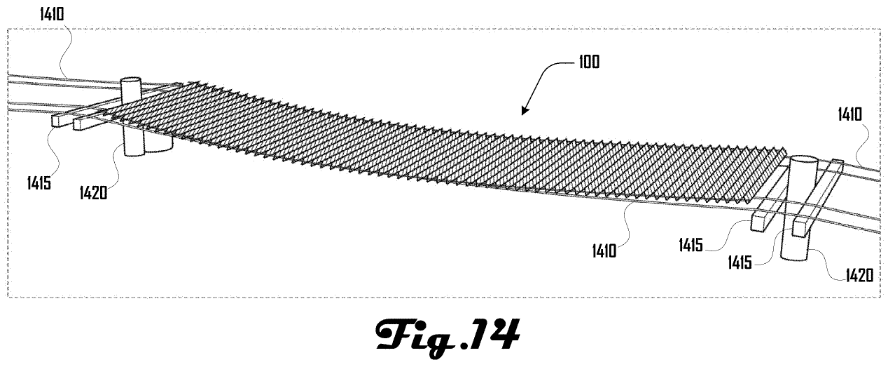

Turning to FIG. 14, another embodiments of a solar system 100 is illustrated that comprises one or more corrugated solar modules 110 held by a plurality of cables 1410, with the one or more corrugated solar modules 110 assuming a curved configuration (e.g., based on flex of the plurality of cables 1410 and flex of the one or more corrugated solar modules 110 about corrugations of the one or more corrugated solar modules 110). In the example of FIG. 14, the cables 1410 are held on crossarms 1415 that are disposed on poles 1420. In some embodiments, the cables 1410 can support the one or more corrugated solar modules 110 and/or transmit power generated by the one or more corrugated solar modules 110. For example, in some embodiments, a first pair of cables 1410 can support the one or more corrugated solar modules 110 and a second pair of cables can transmit electrical power generated by the one or more corrugated solar modules 110. For example, in some embodiments, the one or more corrugated solar modules 110 can comprise a plurality of coupling slots 2320 as shown in FIGS. 23a, 23b and 23c, which can allow the one or more corrugated solar modules 110 to be suspended by support cables 1410 via the slots 2320.

Solar tracking can be implemented in some instantiations. Additional tensile members (e.g., cables 1410) can be utilized in some examples to increase the stiffness of a tensile structure, for example, an inverse suspension bridge type tensile structure to help reduce aerodynamic oscillations. Or in a simple example case, a direct bridle from the base of a post 1415 to a main tensile member some distance along the span, pulling it down and preventing it from substantially oscillating up and down at that point.

In some instantiations, the tensile wires or cables can provide a support structure for electrical wiring. The site can, for example, be prepared by installing tensile wires, hanging electrical wires from them, and then placing photovoltaic modules. This can allow easy access during the wiring process, simplifying installation. Power may be transmitted from the one or more modules 110 to the electrical wires using insulation displacement connectors (IDCs) or other inline connectors.

In some instantiations, the earth itself can be profiled to better accommodate the solar modules 110 and to reduce the need for external structure. The general concept being to maximize the use of the earth as structure, thereby minimizing the need for additional structure. For example, the earth can be profiled to an angle that better collects solar energy allowing solar modules 110 to be located in closer proximity to the ground with shorter posts while the solar modules 110 are still angled at a more optimal elevation angle for solar energy collection. This can, in some examples, allow for more smaller posts, reducing the tensile span between posts and thereby the strength/mass/cost of tensile members required to support the solar modules 110.

In some instantiations, the posts can be angled orthogonally to the solar modules 110, which can be at some given elevation angle. As aerodynamic pressure loads upon the solar module(s) 110 can only act orthogonally to the solar module surface, in various examples, such loads can ensure that post loads are axial only, avoiding substantial post bending moments and thereby allowing for lighter weight and lower cost posts in some embodiments.

In some instantiations, the corrugation axis may be oriented in the east-west direction and photovoltaic cells supplied only on the faces inclined in the direction of solar exposure (e.g., only on first or second sidewalls 325 as discussed herein). This can allow the module 110 to be mounted in a flat orientation close to the ground (and thus minimizing wind loads), while still orienting the photovoltaic cells 305 at the optimal elevation angle.

Tensile member structural support can be used in some examples in conjunction with other structures that might be otherwise difficult to mount solar modules to. For example, tensile member structural support can be used for the direct construction of solar awnings, or for covering building structures that lack easy mounting points or which are of inconvenient shape for direct solar module mounting.

In some instantiations, shingled arrangements of photovoltaic cells can be used within the corrugated solar module 110. This arrangement can, in some examples, strengthen the solar module 110 and reduce stress concentrations. Further, due to the larger cross-sectional area and shorter length of the cell-to-cell connections, some examples can allow the use of electrically conductive adhesive, rather than tabbing wire. This approach can simplify the manufacturing process by reducing part counts (e.g., without tabbing wires between each cell) and process steps (e.g., flux application, tabbing wire placement, and soldering).

In some embodiments, a corrugated photovoltaic structure or solar module 110 may not be supplied in individual panels, but instead on a continuous roll with axis parallel to the corrugation bends, leveraging the relative compliance in this direction. This can be desirable in some examples for rapidly deployable installations, as all wiring can be integral to the laminate in some embodiments. In these cases, similar machinery to turf-rolling tractors could be used for rapid deployment.

In some such embodiments a unitary rolled sheet solar module 110 can be un-rolled and installed as a unitary rolled sheet solar module 110; however, in some embodiments, a unitary rolled sheet solar module 110 can be configured to be cut to size to generate any suitable plurality of separate solar modules 110 of various suitable sizes. For example, in some embodiments, rows 340 of solar cells 305 can be configurated to be separated or cut such than any suitable plurality of N-rows solar modules 110 can be generates. In such an example, having electrical lines 345 extending between columns 340 of solar cells 305 at ends of the rows 340. Such an embodiment can also include a flat sheet bonded to each corrugation (similar to single-ply corrugated cardboard), which can provide extensional stability.

The described embodiments are susceptible to various modifications and alternative forms, and specific examples thereof have been shown by way of example in the drawings and are herein described in detail. It should be understood, however, that the described embodiments are not to be limited to the particular forms or methods disclosed, but to the contrary, the present disclosure is to cover all modifications, equivalents, and alternatives. Additionally, elements of a given embodiment should not be construed to be applicable to only that example embodiment and therefore elements of one example embodiment can be applicable to other embodiments. Additionally, elements that are specifically shown in example embodiments should be construed to cover embodiments that comprise, consist essentially of, or consist of such elements, or such elements can be explicitly absent from further embodiments. Accordingly, the recitation of an element being present in one example should be construed to support some embodiments where such an element is explicitly absent.

What is claimed is:

1. A system comprising:
a plurality of corrugated solar modules coupled to a roof of a building, each of the plurality of corrugated solar modules comprising a plurality of solar cells disposed between a substrate layer and a transparent or translucent top layer, each of the plurality of corrugated solar modules having an undulating structure having a plurality of corrugations defined by:
a plurality of alternating elongated concave top channels and elongated concave bottom channels that extend between opposing ends along first parallel axes, the elongated concave bottom channels defined by first pairs of sidewalls extending from respective caps, and the elongated concave top channels defined by second sidewalls extending from respective bases,
faces of the caps disposed in a first common plane that is parallel to the first parallel axes of the elongated concave top channels and the elongated concave bottom channels,
faces of the bases disposed in a second common plane that is parallel to the first parallel axes of the elongated concave top channels and the elongated concave bottom channels and parallel to the first common plane of the faces of the caps,
wherein the plurality of solar cells are disposed in a plurality of parallel cell rows that extend along second parallel axes that are parallel to the first parallel axes, with each of the cell rows of the plurality of parallel cell rows disposed on a different sidewall, with no more than one cell row disposed on a given sidewall, and with each of the cell rows defined by a 1×N row of solar cells, and
wherein adjacent cell rows of the plurality of cell rows are electrically coupled via electrical lines that extend over caps and bases only at one or both of the opposing ends of the solar module; and
a plurality of fasteners that extend through the caps of the corrugated solar modules to couple the corrugated solar modules to the roof of the building.

2. The system of claim 1, wherein the sidewalls, caps and bases are substantially planar with the sidewalls extending from the caps and bases at 1350 such that planes of symmetry extend perpendicularly through the caps and bases, the planes of symmetry parallel to the first parallel axes of the elongated concave top channels and the elongated concave bottom channels.

3. The system of claim 1,
wherein the sidewalls have the same width as each other;
wherein the caps have the same width as each other;
wherein the bases have the same width as each other; and
wherein the caps and bases have a smaller width than the width of the sidewalls.

4. The system of claim 1, wherein cell rows of the plurality of cell rows are disposed on every other adjacent sidewall with cell rows being absent on respective single sidewalls between adjacent cell rows.

5. The system of claim 1, wherein one or more ends of the corrugated solar modules are sealed via one or more of:
a sealing tape disposed at an end of a solar module between the top layer and the substrate layer;
a U-seal disposed surrounding an end of a solar module, including surrounding an end of the top layer, an end of the substrate layer and an end of internal elements between the top layer and the substrate layer to provide a seal protecting the internal elements; and
a rolled edge at an end of a solar module defined by rolled ends of the top layer and the substrate layer that provide a seal protecting internal elements of the solar module.

6. The system of claim 1, wherein adjacent pairs of solar modules of the plurality of solar modules are coupled at a respective elongated overlapping area with an elongated seal between the solar modules, the adjacent pairs of solar modules including a top module disposed over a bottom module at corresponding caps and sidewalls with the elongated seal disposed along a first cap of the bottom module engaging a bottom of a second cap of the top module to generate a seal between the top module and bottom module.

7. A system comprising:
a plurality of corrugated solar modules, each of the plurality of corrugated solar modules comprising a plurality of solar cells disposed between a substrate layer and a transparent or translucent top layer, each of the plurality of corrugated solar modules having a plurality of corrugations defined by:
a plurality of alternating elongated concave top channels and elongated concave bottom channels that extend between opposing ends along first parallel axes, the elongated concave bottom channels defined by first pairs of sidewalls extending from respective caps, and the elongated concave top channels defined by second sidewalls extending from respective bases,
faces of the caps disposed in a first common plane that is parallel to the first parallel axes of the elongated concave top channels and the elongated concave bottom channels,
faces of the bases disposed in a second common plane that is parallel to the first parallel axes of the elongated concave top channels and the elongated concave bottom channels and parallel to the first common plane of the faces of the caps,
wherein the plurality of solar cells are disposed in a plurality of parallel cell rows that extend along second parallel axes that are parallel to the first parallel axes, with each of the cell rows of the plurality of parallel cell rows disposed on a different sidewall, with no more than one cell row disposed on a given sidewall, and with each of the cell rows defined by a 1×N row of solar cells, and
wherein adjacent cell rows of the plurality of cell rows are electrically coupled via electrical lines that extend over caps and bases only at one or both of the opposing ends of the solar module.

8. The system of claim 7, wherein the plurality of corrugated solar modules are coupled to a building via a plurality of fasteners that extend through the caps of the corrugated solar modules to couple the corrugated solar modules to the building.

9. The system of claim 7, wherein a plurality of the sidewalls, caps and bases are substantially planar with the sidewalls extending from the caps such that planes of symmetry extend perpendicularly through the caps and bases, the planes of symmetry parallel to the first parallel axes of the elongated concave top channels and the elongated concave bottom channels.

10. The system of claim 7, wherein
a plurality of the sidewalls have the same width as each other;
a plurality of the caps have the same width as each other;
a plurality of bases have the same width as each other; and
the plurality of the caps and plurality of bases have a smaller width than the width of the plurality of the sidewalls.

11. The system of claim 7, wherein cell rows of the plurality of cell rows are disposed with cell rows being absent on respective single sidewalls between adjacent cell rows.

12. The system of claim 7, wherein one or more ends of the corrugated solar modules are sealed via one or more of:
a first seal disposed at an end of a solar module between the top layer and the substrate layer;
a second disposed surrounding an end of a solar module, including surrounding an end of the top layer, an end of the substrate layer and an end of internal elements between the top layer and the substrate layer to provide a seal protecting the internal elements; and
a third seal at an end of a solar module defined by rolled ends of the top layer and the substrate layer that provide a seal protecting internal elements of the solar module.

13. The system of claim 7, wherein adjacent pairs of solar modules of the plurality of solar modules are coupled at a respective overlapping area with a seal between the solar modules, the adjacent pairs of solar modules including a top module disposed over a bottom module at corresponding caps and sidewalls with the seal disposed along a first cap of the bottom module engaging a bottom of a second cap of the top module to generate a seal between the top module and bottom module.

14. A system comprising:
one or more solar modules comprising a plurality of solar cells, each of the solar modules having a plurality of corrugations defined by:
a plurality of alternating elongated top channels and elongated bottom channels that extend between opposing ends along first parallel axes, the elongated bottom channels defined by first pairs of sidewalls extending from respective caps, and the elongated top channels defined by second sidewalls extending from respective bases.

15. The system of claim 14, wherein the plurality of solar cells are disposed between a substrate layer and a transparent or translucent top layer.

16. The system of claim 14, wherein the plurality of corrugations are further defined by faces of the caps disposed in a first common plane that is parallel to the first parallel axes of the elongated top channels and the elongated bottom channels.

17. The system of claim 14, wherein the plurality of corrugations are further defined by faces of the bases disposed in a second common plane that is parallel to the first parallel axes of the elongated top channels and the elongated bottom channels.

18. The system of claim 14, wherein the plurality of solar cells are disposed in a plurality of parallel cell rows that extend along second parallel axes that are parallel to the first parallel axes, with each of the cell rows of the plurality of parallel cell rows disposed on a different sidewall, with no more than one cell row disposed on a given sidewall, and with each of the cell rows defined by a 1×N row of solar cells.

19. The system of claim 14, wherein adjacent cell rows of the plurality of cell rows are electrically coupled via electrical lines that extend over caps and bases only at one or both of the opposing ends.

20. The system of claim 14, wherein
a plurality of the sidewalls have the same width as each other;
a plurality of the caps have the same width as each other;
a plurality of bases have the same width as each other; and
the plurality of the caps and plurality of bases have a smaller width than the width of the plurality of the sidewalls.
